(19) United States
(12) Patent Application Publication
(10) Pub. No.: US 2021/0222010 A1
(43) Pub. Date: Jul. 22, 2021

(54) COLORING COMPOSITION, FILM, COLOR FILTER, METHOD FOR MANUFACTURING COLOR FILTER, STRUCTURE BODY, SOLID-STATE IMAGING ELEMENT, AND IMAGE DISPLAY DEVICE

(71) Applicant: FUJIFILM Corporation, Tokyo (JP)

(72) Inventor: Shoichi NAKAMURA, Shizuoka (JP)

(73) Assignee: FUJIFILM Corporation, Tokyo (JP)

(21) Appl. No.: 17/223,006

(22) Filed: Apr. 6, 2021

Related U.S. Application Data
(63) Continuation of application No. PCT/JP2019/038685, filed on Oct. 1, 2019.

(30) Foreign Application Priority Data
Oct. 11, 2018 (JP) 2018-192563

(51) Int. Cl. C09B 47/04; C09B 57/00; C09D 7/20; C09D 201/08; G03F 7/00; G03F 7/16; G02B 5/20

(52) U.S. Cl. CPC C09B 47/04; C09B 57/004; C09D 7/20; G02B 5/20; G03F 7/0007; G03F 7/168; C09D 201/08

(57) ABSTRACT

Provided are a coloring composition including a pigment, a pigment derivative, a resin, and a solvent, in which an average primary particle diameter of the pigment is 70 nm or less, an average primary particle diameter of the pigment derivative is 70 nm or less, and the solvent includes a solvent D1 having a solubility parameter of 18.0 to 26.0 MPa^{0.5}; a film formed of a coloring composition; a color filter; a method for manufacturing a color filter; a structure body; a solid-state imaging element; and an image display device.

### CROSS-REFERENCE TO RELATED APPLICATIONS

This application is a Continuation of PCT International Application No. PCT/JP2019/038685 filed on Oct. 1, 2019, which claims priority under 35 U.S.C § 119(a) to Japanese Patent Application No. 2018-192563 filed on Oct. 11, 2018. Each of the above application(s) is hereby expressly incorporated by reference, in its entirety, into the present application.

### BACKGROUND OF THE INVENTION

### 1. Field of the Invention

The present invention relates to a coloring composition including a pigment. The present invention further relates to a film formed of the coloring composition, a color filter, a method for manufacturing a color filter, a structure body, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. As a key device of a display or an optical element, a color filter has been used. The color filter normally includes pixels of three primary colors of red, green, and blue, and acts to separate transmitted light into the three primary colors.

As disclosed in JP2017-138417A, each color pixel (colored layer) of the color filter has been manufactured by using a coloring composition including a colorant such as a pigment, a pigment derivative, and a resin.

### SUMMARY OF THE INVENTION

In recent years, an attempt to suppress color mixing between pixels by separating pixels of each color in a color filter with a partition wall has also been studied. In addition, in recent years, the pixels of each color in the color filter have been miniaturized. In particular, in the color filter having a structure in which the pixels of each color are separated by the partition wall, the pixel size is further miniaturized.

In a film used for a color filter or the like, it is desired that there is little color unevenness. In addition, as the pixel size is finer, it is required to suppress color unevenness at a higher level. In addition, in the film used for a color filter or the like, further improvement in light resistance has been required.

According to the studies conducted by the present inventor, a film obtained from the coloring composition disclosed in JP2017-138417A has not reached the level required in recent years for properties such as light resistance and color unevenness, and it is found that there is room for further improvement.

Accordingly, an object of the present invention is to provide a coloring composition with which a film having small color unevenness and excellent light resistance can be formed. Another object of the present invention is to provide a film formed of the coloring composition, a color filter, a method for manufacturing a color filter, a structure body, a solid-state imaging element, and an image display device.

According to the studies conducted by the present inventor, it has been found that the above-described object can be achieved by adopting the following configuration, thereby leading to the completion of the present invention. Therefore, the present invention provides the following.

<1> A coloring composition comprising:

a pigment;

a pigment derivative;

a resin; and

a solvent,

in which an average primary particle diameter of the pigment is 70 nm or less,

an average primary particle diameter of the pigment derivative is 70 nm or less, and

the solvent includes a solvent D1 having a solubility parameter of 18.0 to 26.0 MPa^{0.5}.

<2> The coloring composition according to <1>,

in which the solvent D1 is included in an amount of 5 mass % or more in a total amount of the solvent.

<3> The coloring composition according to <1> or <2>, in which the solvent further includes a solvent D2 having a solubility parameter of less than 18 MPa^{0.5}.

<4> The coloring composition according to <3>,

in which a content of the solvent D2 is 500 to 5000 parts by mass with respect to 100 parts by mass of the solvent D1.

<5> The coloring composition according to any one of <1> to <4>,

in which the pigment includes at least one selected from a diketopyrrolopyrrole compound and a phthalocyanine compound.

<6> The coloring composition according to any one of <1> to <5>,

in which the pigment is contained in an amount of 50 mass % or more in a total solid content of the coloring composition.

<7> The coloring composition according to any one of <1> to <6>,

in which the resin includes a resin having an aromatic carboxyl group.

<8> The coloring composition according to <7>,

in which the resin having an aromatic carboxyl group is a resin including a repeating unit represented by Formula (b-1),

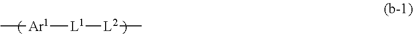

in the formula, Ar¹ represents a group including an aromatic carboxyl group, L¹ represents —COO— or —CONH—, and L² represents a divalent linking group.

<9> The coloring composition according to any one of <1> to <8>,

in which the resin contains a resin including a repeating unit derived from a compound represented by Formula (I),

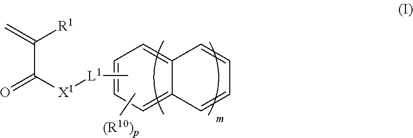

in the formula, X¹ represents O or NH,

R¹ represents a hydrogen atom or a methyl group,

L¹ represents a divalent linking group,

R¹⁰ represents a substituent,

m represents an integer of 0 to 2, and

p represents an integer of 0 or more.

<10> The coloring composition according to <9>,

in which the resin including the repeating unit derived from the compound represented by Formula (I) further includes a repeating unit derived from an alkyl (meth)acrylate.

<11> The coloring composition according to any one of <1> to <10>, further comprising:

a compound including a furyl group.

<12> The coloring composition according to any one of <1> to <11>, further comprising:

a polymerizable monomer.

<13> The coloring composition according to any one of <1> to <12>, further comprising:

a photopolymerization initiator.

<14> The coloring composition according to any one of <1> to <13>,

in which the coloring composition is used for a color filter.

<15> The coloring composition according to any one of <1> to <14>,

in which the coloring composition is used for a solid-state imaging element.

<16> The coloring composition according to any one of <1> to <15>,

in which the coloring composition is used for forming a colored layer in a region partitioned by a partition wall.

<17> A film obtained from the coloring composition according to any one of <1> to <16>.

<18> A color filter comprising:

the film according to <17>.

<19> A method for manufacturing a color filter, comprising:

a step of forming a coloring composition layer on a support using the coloring composition according to any one of <1> to <16>; and

a step of forming a pattern on the coloring composition layer by a photolithography method.

<20> A structure body comprising:

a support;

a partition wall provided on the support; and

a colored layer obtained from the coloring composition according to any one of <1> to <16> and provided on a region of the support partitioned by the partition wall.

<21> A solid-state imaging element comprising:

the film according to <17>.

<22> An image display device comprising:

the film according to <17>.

According to the present invention, it is possible to provide a coloring composition with which a film having small color unevenness and excellent light resistance can be formed. It is also possible to provide a film formed of a coloring composition, a color filter, a method for manufacturing a color filter, a structure body, a solid-state imaging element, and an image display device.

### BRIEF DESCRIPTION OF THE DRAWINGS

FIG. 1 is a side-sectional view showing an embodiment of a structure body according to the present invention.

FIG. 2 is a plan view of the structure body as viewed from directly above a support.

### DESCRIPTION OF THE PREFERRED EMBODIMENTS

Hereinafter, the details of the present invention will be described.

In the present specification, numerical ranges represented by “to” include numerical values before and after “to” as lower limit values and upper limit values.

In the present specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In the present specification, unless specified otherwise, “exposure” denotes not only exposure using light but also drawing using a corpuscular beam such as an electron beam or an ion beam. Examples of the light used for exposure include an actinic ray or radiation, for example, a bright light spectrum of a mercury lamp, a far ultraviolet ray represented by excimer laser, an extreme ultraviolet ray (EUV ray), an X-ray, or an electron beam.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in structural formulae, Me represents a methyl group, Et represents an ethyl group, Bu represents a butyl group, and Ph represents a phenyl group.

In the present specification, a weight-average molecular weight and a number-average molecular weight are values in terms of polystyrene measured by gel permeation chromatography (GPC) method.

In the present specification, a total solid content denotes the total mass of all the components of the composition excluding a solvent.

In the present specification, a pigment means a compound which is hardly dissolved in a solvent.

In the present specification, the term “step” denotes not only an individual step but also a step which is not clearly distinguishable from another step as long as an effect expected from the step can be achieved.

<Coloring Composition>

A coloring composition according to an embodiment of the present invention includes:

a pigment;

a pigment derivative;

a resin; and

a solvent,

in which an average primary particle diameter of the pigment is 70 nm or less,

an average primary particle diameter of the pigment derivative is 70 nm or less, and

the solvent includes a solvent D1 having a solubility parameter of 18.0 to 26.0 MPa^{0.5}.

Since the average primary particle diameter of each of the pigment and pigment derivative included in the coloring composition according to the embodiment of the present invention is 70 nm or less, it is possible to suppress occurrence of unevenness on a coated surface during film formation. In addition, in general, the pigment derivative has high activity and tends to aggregate and coarsen, but the coloring composition according to the embodiment of the present invention includes the solvent D1 having the above-described solubility parameter. Therefore, it is presumed that aggregation of the pigment derivative and aggregation of the pigment can be suppressed due to increase in affinity between the pigment derivative and the solvent. Accordingly, it is presumed that the coloring composition according to the embodiment of the present invention can form a film in which color unevenness is suppressed.

In addition, since the coloring composition according to the embodiment of the present invention uses a pigment derivative having an average primary particle diameter of 70 nm or less, a film having excellent light resistance can be formed. The reason for this is presumed to be as follows. It is presumed that, as the particle diameter of the pigment derivative is smaller, a surface area per unit mass is larger and the adsorption to the pigment is better. It is presumed that a pigment activated by light can be inactivated due to the adsorption of the pigment derivative to the pigment, so that decomposition and the like of the pigment or pigment derivative due to the light irradiation can be suppressed. Since the pigment derivative used in the coloring composition according to the embodiment of the present invention has a small particle diameter, it is presumed that the pigment derivative has high adsorptivity to the pigment. Therefore, it is presumed that the decomposition of the pigment or pigment derivative due to light irradiation can be suppressed and excellent light resistance is obtained.

In the present specification, the average primary particle diameter of the pigment and the pigment derivative is measured by directly measuring the size of the primary particle of the measurement sample from an electron micrograph using a transmission electron microscope (TEM). Specifically, the minor axis diameter and the major axis diameter of the primary particle of each pigment are measured, and the average thereof is defined as the particle diameter of the primary pigment. Next, for each of the 100 pigment particles, the volume of each pigment particle is obtained by approximating it to a cube having the obtained particle diameter, and the volume average particle diameter is defined as the average primary particle diameter. The pigment derivative is also measured by the same method.

In addition, in the present specification, the solubility parameter of the solvent is a value calculated by Fedors method.

The coloring composition according to the embodiment of the present invention can be preferably used as a coloring composition for a color filter. Specifically, the coloring composition of the embodiment of the present invention can be preferably used as a coloring composition for forming pixels of a color filter. In addition, the coloring composition according to the embodiment of the present invention can be preferably used as a coloring composition for a solid-state imaging element, and can be more preferably used as a coloring composition for forming pixels of a color filter used in a solid-state imaging element. In addition, the coloring composition according to the embodiment of the present invention can also be preferably used as a coloring composition for a display device, and can be more preferably used as a coloring composition for forming pixels of a color filter used in a display device. In addition, the coloring composition according to the embodiment of the present invention is preferably used for forming a colored layer in a region partitioned by a partition wall.

Hereinafter, the coloring composition according to the embodiment of the present invention will be described in detail.

«Pigment»

The coloring composition according to the embodiment of the present invention contains a pigment. Examples of the pigment include chromatic pigments such as red pigment, green pigment, blue pigment, yellow pigment, violet pigment, and orange pigment. The pigment may be either an inorganic pigment or an organic pigment. In addition, as the pigment, a material in which a part of an inorganic pigment or an organic-inorganic pigment is replaced with an organic chromophore can also be used. By substituting an inorganic pigment or an organic-inorganic pigment with an organic chromophore, color tone design can be easily performed.

The average primary particle diameter of the pigment used in the present invention is 70 nm or less, and from the reason that the effects of the present invention can be easily obtained more remarkably, is preferably 60 nm or less and more preferably 50 nm or less. From the reason that it is easy to suppress reaggregation of the pigment, the lower limit is preferably 10 nm or more.

In a case where the coloring composition according to the embodiment of the present invention includes two or more kinds of pigments, the average primary particle diameter of each pigment is preferably 70 nm or less, more preferably 60 nm or less, and still more preferably 50 nm or less.

Examples of the type of the pigment used in the present invention include the following.

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 231, 232 (methine/polymethine-based), and the like (all of which are yellow pigments);

C. I. Pigment Orange 2, 5, 13, 16, 17:1, 31, 34, 36, 38, 43, 46, 48, 49, 51, 52, 55, 59, 60, 61, 62, 64, 71, 73, and the like (all of which are orange pigments);

C. I. Pigment Green 7, 10, 36, 37, 58, 59, 62, 63, and the like (all of which are green pigments);

C. I. Pigment Violet 1, 19, 23, 27, 32, 37, 42, 60 (triarylmethane-based), 61 (xanthene-based), and the like (all of which are violet pigments);

C. I. Pigment Blue 1, 2, 15, 15:1, 15:2, 15:3, 15:4, 15:6, 16, 22, 29, 60, 64, 66, 79, 80, 87 (monoazo-based), 88 (methine/polymethine-based), and the like (all of which are blue pigments); and

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 279, 294 (xanthene-based, Organo Ultramarine, Bluish Red), and the like (all of which are red pigments)

In addition, as the green pigment, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used. Specific examples thereof include compounds described in WO2015/118720A. In addition, as the green pigment, compounds described in CN2010-6909027A, a phthalocyanine compound having a phosphoric acid ester as a ligand, or the like can also be used.

In addition, as the blue pigment, an aluminum phthalocyanine compound having a phosphorus atom can also be used. Specific examples thereof include compounds described in paragraphs “0022” to “0030” of JP2012-247591A and paragraph “0047” of JP2011-157478A.

In addition, as the yellow pigment, pigments described in JP2017-201003A, pigments described in JP2017-197719A, pigments described in paragraphs “0011” to “0062” and “0137” to “0276” of JP2017-171912A, pigments described in paragraphs “0010” to “0062” and “0138” to “0295” of JP2017-171913A, pigments described in paragraphs of “0011” to “0062” and “0139” to “0190” of JP2017-171914A, and pigments described in paragraphs “0010” to “0065” and “0142” to “0222” of JP2017-171915A can also be used. In addition, as the yellow pigment, compounds described in JP2018-062644A can also be used.

In addition, as the red pigment, brominated diketopyrrolopyrrole pigments described in JP2017-201384A, in which the structure has at least one substituted bromine atom, diketopyrrolopyrrole pigments described in paragraphs “0016” to “0022” of JP6248838B, diketopyrrolopyrrole pigments described in paragraphs “0020” to “0032” of JP2017-138417A, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used.

The pigment used in the present invention is also preferably at least one selected from a diketopyrrolopyrrole compound and a phthalocyanine compound. In a case where these compounds are used as the pigment, the effects of the present invention can be easily obtained more remarkably.

The pigment used in the present invention is also preferably at least one selected from the brominated diketopyrrolopyrrole pigment, C. I. Pigment Red 122, C. I. Pigment Red 177, C. I. Pigment Red 254, C. I. Pigment Red 264, C. I. Pigment Red 272, C. I. Pigment Orange 71, C. I. Pigment Yellow 138, C. I. Pigment Yellow 139, C. I. Pigment Yellow 150, C. I. Pigment Yellow 185, C. I. Pigment Green 7, C. I. Pigment Green 36, C. I. Pigment Green 58, C. I. Pigment Green 59, C. I. Pigment Violet 23, C. I. Pigment Blue 15:6, and C. I. Pigment Blue 16.

The content of the pigment in the total solid content of the coloring composition is preferably 20 mass % or more, more preferably 30 mass % or more, still more preferably 40 mass % or more, and particularly preferably 50 mass % or more. The upper limit is preferably 80 mass % or less and more preferably 75 mass % or less.

«Pigment Derivative»

The coloring composition according to the embodiment of the present invention contains a pigment derivative. The pigment derivative is used as a dispersion aid for the pigment. Examples of the pigment derivative include a compound having a structure in which a part of the pigment is replaced with an acid group or a basic group.

The average primary particle diameter of the pigment derivative used in the present invention is 70 nm or less, and from the reason that the effects of the present invention can be easily obtained more remarkably, is preferably 60 nm or less and more preferably 50 nm or less. From the reason that it is easy to suppress reaggregation of the pigment derivative, the lower limit is preferably 10 nm or more.

The average primary particle diameter of the pigment derivative used in the present invention may be smaller, larger, or the same as the average primary particle diameter of the pigment. From the reason that it is easy to suppress the color unevenness, it is preferable that the average primary particle diameter of the pigment derivative and the average primary particle diameter of the pigment are almost the same. In addition, the absolute value of the difference between the average primary particle diameter of the pigment derivative and the average primary particle diameter of the pigment is preferably 0 to 30 nm. The upper limit is preferably 20 nm or less and still more preferably 15 nm or less.

In a case where the coloring composition according to the embodiment of the present invention includes two or more kinds of pigment derivatives, the average primary particle diameter of each pigment derivative is preferably 70 nm or less, more preferably 60 nm or less, and still more preferably 50 nm or less.

The pigment derivative used in the present invention is preferably a compound represented by Formula (syn1).

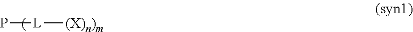

In Formula (syn1), P represents a colorant structure, L represents a single bond or a linking group, X represents an acid group or a basic group, m represents an integer of 1 or more, n represents an integer of 1 or more, in a case where m represents 2 or more, a plurality of L's and a plurality of X's may be different from each other, and in a case where n represents 2 or more, a plurality of X's may be different from each other.

Examples of the colorant structure represented by P in Formula (syn1) include a quinoline colorant structure, a benzimidazolone colorant structure, an isoindoline colorant structure, a diketopyrrolopyrrole colorant structure, an azo colorant structure, a phthalocyanine colorant structure, an anthraquinone colorant structure, a quinacridone colorant structure, a dioxazine colorant structure, a perylene colorant structure, a perinone colorant structure, a thiodin indigo colorant structure, an isoindolinone colorant structure, and a quinophthalone colorant structure. Among these, an azo colorant structure, a quinoline colorant structure, an anthraquinone colorant structure, a quinophthalone colorant structure, a benzoimidazolone colorant structure, or a phthalocyanine colorant structure is preferable.

In Formula (syn1), L represents a single bond or a linking group, and preferably represents a linking group. Examples of the divalent linking group include an alkylene group, an arylene group, a nitrogen-containing heterocyclic group, —O—, —S—, —NR′—, —CO—, —COO—, —OCO—, —SO₂—, or a group formed by a combination of these groups, and it is preferable that the divalent linking group is an alkylene group or a group having an alkylene group. R′ represents a hydrogen atom, an alkyl group, or an aryl group. In a case where L is a tri- or more valent linking group, a group in which one or more hydrogen atom is removed from the above-described divalent linking group is exemplified.

The number of carbon atoms in the alkylene group is preferably 1 to 30, more preferably 1 to 15, and still more preferably 1 to 10. The alkylene group may have a substituent. The alkylene group may be linear, branched, or cyclic. In addition, the cyclic alkylene group may be monocyclic or polycyclic.

The number of carbon atoms in the arylene group is preferably 6 to 18, more preferably 6 to 14, and still more preferably 6 to 10.

The nitrogen-containing heterocyclic group is preferably a 5-membered ring or a 6-membered ring. In addition, the nitrogen-containing heterocyclic group is preferably a single ring or a fused ring, more preferably a single ring or a fused ring having 2 to 8 fused numbers, and still more preferably a single ring or a fused ring having 2 to 4 fused numbers. The number of nitrogen atoms included in the nitrogen-containing heterocyclic group is preferably 1 to 3 and more preferably 1 or 2. The nitrogen-containing heterocyclic group may include a heteroatom other than a nitrogen atom. Examples of the heteroatom other than a nitrogen atom include an oxygen atom and a sulfur atom. The number of the heteroatoms other than a nitrogen atom is preferably 0 to 3 and more preferably 0 or 1. Examples of the nitrogen-containing heterocyclic group include a piperazine ring group, a pyrrolidine ring group, a pyrrole ring group, a piperidine ring group, a pyridine ring group, an imidazole ring group, a pyrazole ring group, an oxazole ring group, a thiazole ring group, a pyrazine ring group, a morpholine ring group, a thiazine ring group, an indole ring group, an isoindole ring group, a benzimidazole ring group, a purine ring group, a quinoline ring group, an isoquinoline ring group, a quinoxaline ring group, a cinnoline ring group, a carbazole ring group, and groups represented by Formulae (L-1) to (L-7).

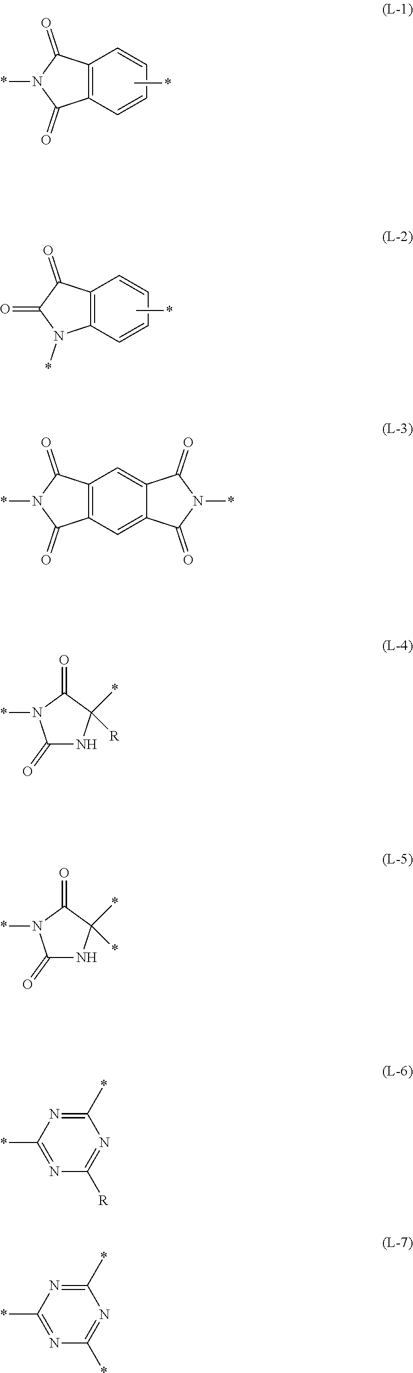

* in the formulae represents a linking hand. R represents a hydrogen atom or a substituent. Examples of the substituent include the substituent T described later.

In Formula (syn1), X represents an acid group or a basic group.

The acid group represented by X is preferably at least one selected from a carboxyl group, a sulfo group, a phosphoric acid group, or salts thereof, and more preferably at least one selected from a carboxyl group, a sulfo group, or salts thereof. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion.

The basic group represented by X is preferably at least one selected from an amino group, a pyridyl group, salts thereof, a salt of an ammonium group, or a phthalimidomethyl group, more preferably at least one selected from an amino group, a salt of an amino group, or a salt of an ammonium group, and more preferably an amino group or a salt of an amino group. Examples of the amino group include —NH₂, a dialkylamino group, an alkylarylamino group, a diarylamino group, and a cyclic amino group. Examples of an atom or atomic group constituting the salts include a hydroxide ion, a halogen ion, a carboxylate ion, a sulfonate ion, and a phenoxide ion.

In Formula (syn1), m is preferably 1 to 10, more preferably 1 to 5, and still more preferably 1 or 2.

In Formula (syn1), n is preferably 1 to 4, more preferably 1 to 3, and still more preferably 1 or 2.

Examples of the pigment derivative include compounds described in Examples described later. In addition, compounds described in JP1981-118462A (JP-S56-118462A), JP1988-264674A (JP-S63-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraphs “0086” to “0098” of WO2011/024896A, paragraphs “0063” to “0094” of WO2012/102399A, paragraph “0082” of WO2017/038252A, paragraphs “0054” to “0074” of JP2017-138417A can also be used, the contents of which are incorporated herein by reference.

The content of the pigment derivative is preferably 1 to 30 parts by mass with respect to 100 parts by mass of the pigment. The lower limit is preferably 2 parts by mass or more and more preferably 3 parts by mass or more. The upper limit is preferably 25 parts by mass or less, more preferably 20 parts by mass or less, and still more preferably 15 parts by mass or less. The pigment derivative may be used singly or in combination of two or more kinds thereof. In a case where two or more kinds thereof are used in combination, the total content thereof is preferably within the above-described range.

In addition, the total content of the pigment and the pigment derivative is preferably 30 to 80 mass % in the total solid content of the coloring composition. The lower limit is preferably 30 mass % or more and more preferably 40 mass % or more. The upper limit is preferably 80 mass % or less, more preferably 75 mass % or less, and still more preferably 70 mass % or less.

«Dye»

The coloring composition according to the embodiment of the present invention can contain a dye. As the dye, a known dye can be used without any particular limitation. Examples thereof include a pyrazoleazo-based dye, an anilinoazo-based dye, a triarylmethane-based dye, an anthraquinone-based dye, an anthrapyridone-based dye, a benzylidene-based dye, an oxonol-based dye, a pyrazolotriazoleazo-based dye, a pyridoneazo-based dye, a cyanine-based dye, a phenothiazine-based dye, a pyrrolopyrazoleazomethine-based dye, a xanthene-based dye, a phthalocyanine-based dye, a benzopyran-based dye, an indigo-based dye, and a pyrromethene-based dye. In addition, thiazole compounds described in JP2012-158649A, azo compounds described in JP2011-184493A, or azo compounds described in JP2011-145540A can also be preferably used. In addition, as a yellow dye, quinophthalone compounds described in paragraphs “0011” to “0034” of JP2013-054339A, quinophthalone compounds described in paragraphs “0013” to “0058” of JP2014-026228A, intramolecular imide type xanthene dyes described in JP2018-012863A, and the like can also be used.

The content of the dye is preferably 50 parts by mass or less, more preferably 40 parts by mass or less, and still more preferably 30 parts by mass or less with respect to 100 parts by mass of the pigment. The lower limit may be 1 part by mass or more or 10 parts by mass or more. In addition, it is also possible that the coloring composition according to the embodiment of the present invention does not contain the dye substantially. The case where the coloring composition according to the embodiment of the present invention does not contain the dye substantially means that the content of the dye in the total solid content of the coloring composition according to the embodiment of the present invention is preferably 0.1 mass % or less, more preferably 0.05 mass % or less, and particularly preferably 0 mass %.

«Resin»

The coloring composition according to the embodiment of the present invention includes a resin. The resin is blended in, for example, an application for dispersing particles such as a pigment in a composition or an application as a binder. Mainly, a resin which is used for dispersing particles and the like in a composition is also referred to as a dispersant. However, such applications of the resin are merely exemplary, and the resin can also be used for other purposes in addition to such applications.

Examples of the resin include a (meth)acrylic resin, a (meth)acrylamide resin, an epoxy resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, a styrene resin, and a siloxane resin.

The weight-average molecular weight (Mw) of the resin is preferably 2000 to 2000000. The upper limit is preferably 1000000 or less and more preferably 500000 or less. The lower limit is preferably 3000 or more, more preferably 4000 or more, and still more preferably 5000 or more.

The coloring composition according to the embodiment of the present invention preferably includes a resin (hereinafter, also referred to as a resin B) having an aromatic carboxyl group. The resin B is preferably a resin having an aromatic carboxyl group and not having a maleimide structure. By using the resin B, it is possible to form a film which does not easily lose color of the pigment during development and has excellent developability.

The resin B may include the aromatic carboxyl group in the main chain of the repeating unit, or in the side chain of the repeating unit. From the reason that the effects described above can be easily obtained more remarkably, it is preferable that the aromatic carboxyl group is included in the main chain of the repeating unit. The details are not clear, but it is presumed that the presence of the aromatic carboxyl group near the main chain further improves these properties. In the present specification, the aromatic carboxyl group is a group having a structure in which one or more carboxyl groups are bonded to an aromatic ring. In the aromatic carboxyl group, the number of carboxyl groups bonded to an aromatic ring is preferably 1 to 4 and more preferably 1 or 2.

The resin B is preferably a resin including at least one repeating unit selected from a repeating unit represented by Formula (b-1) or a repeating unit represented by Formula (b-10).

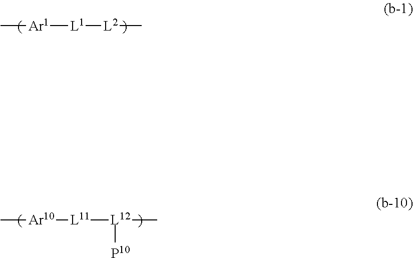

In Formula (b-1), Ar¹ represents a group including an aromatic carboxyl group, L¹ represents —COO— or —CONH—, and L² represents a divalent linking group.

In Formula (b-10), Ar¹⁰ represents a group including an aromatic carboxyl group, L¹¹ represents —COO— or —CONH—, L¹² represents a trivalent linking group, and P¹⁰ represents a polymer chain.

First, Formula (b-1) will be described. In Formula (b-1), examples of the group including an aromatic carboxyl group, represented by Ar¹, include a structure derived from an aromatic tricarboxylic acid anhydride and a structure derived from an aromatic tetracarboxylic acid anhydride. Examples of the aromatic tricarboxylic acid anhydride and the aromatic tetracarboxylic acid anhydride include compounds having the following structures.

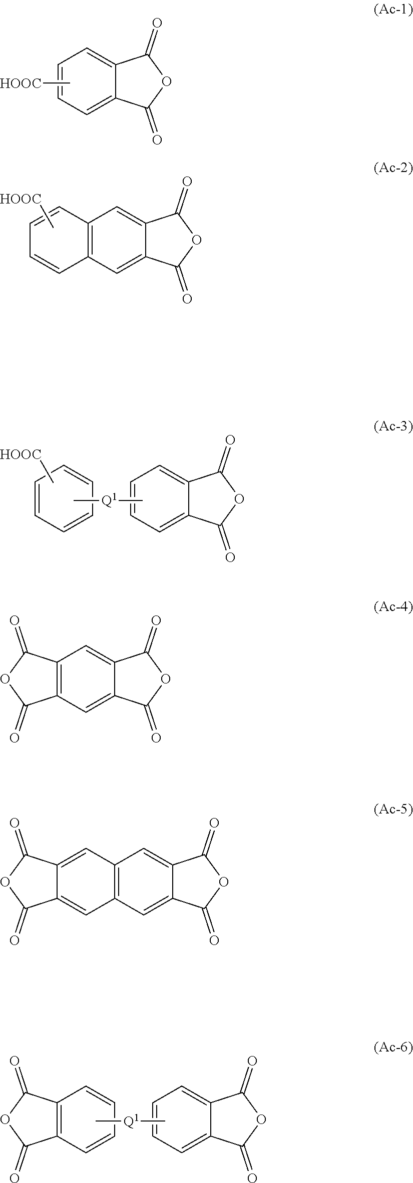

In the formulae, Q¹ represents a single bond, —O—, —CO—, —COOCH₂CH₂OCO—, —SO₂—, —C(CF₃)₂—, a group represented by Formula (Q-1), or a group represented by Formula (Q-2).

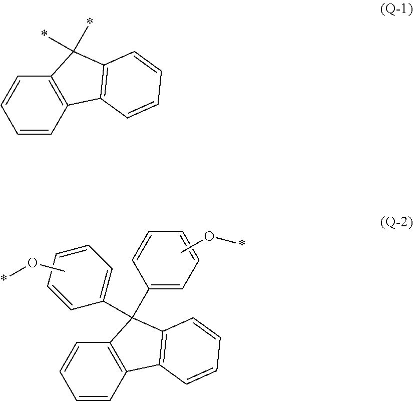

Specific examples of the aromatic tricarboxylic acid anhydride include a benzenetricarboxylic acid anhydride (1,2,3-benzenetricarboxylic acid anhydride, trimellitic acid anhydride [1,2,4-benzenetricarboxylic acid anhydride], and the like), a naphthalenetricarboxylic acid anhydride (1,2,4-naphthalenetricarboxylic acid anhydride, 1,4,5-naphthalenetricarboxylic acid anhydride, 2,3,6-naphthalenetricarboxylic acid anhydride, 1,2,8-naphthalenetricarboxylic acid anhydride, and the like), 3,4,4′-benzophenonetricarboxylic acid anhydride, 3,4,4′-biphenylethertricarboxylic acid anhydride, 3,4,4′-biphenyltricarboxylic acid anhydride, 2,3,2′-biphenyltricarboxylic acid anhydride, 3,4,4′-biphenylmethanetricarboxylic acid anhydride, and 3,4,4′-biphenylsulfonetricarboxylic acid anhydride. Specific examples of the aromatic tetracarboxylic acid anhydride include pyromellitic acid dianhydride, ethylene glycol dianhydrous trimellitic acid ester, propylene glycol dianhydrous trimellitic acid ester, butylene glycol dianhydrous trimellitic acid ester, 3,3′,4,4′-benzophenonetetracarboxylic acid dianhydride, 3,3′,4,4′-biphenylsulfonetetracarboxylic acid dianhydride, 1,4,5,8-naphthalenetetracarboxylic acid dianhydride, 2,3,6,7-naphthalenetetracarboxylic acid dianhydride, 3,3′,4,4′-biphenylethertetracarboxylic acid dianhydride, 3,3′,4,4′-dimethyldiphenylsilanetetracarboxylic acid dianhydride, 3,3′,4,4′-tetraphenylsilanetetracarboxylic acid dianhydride, 1,2,3,4-frantetracarboxylic acid dianhydride, 4,4′-bis(3,4-dicarboxyphenoxy)diphenylsulfide dianhydride, 4,4′-bis(3,4-dicarboxyphenoxy)diphenylsulfonedianhydride, 4,4′-bis(3,4-dicarboxyphenoxy) diphenylpropane dianhydride, 3,3′,4,4′-perfluoroisopropyridendiphthalic acid dianhydride, 3,3′,4,4′-biphenyltetracarboxylic acid dianhydride, bis(phthalic acid) phenylphosphineoxide dianhydride, p-phenylene-bis(triphenylphthalic acid) dianhydride, m-phenylene-bis(triphenylphthalic acid) dianhydride, bis(triphenylphthalic acid)-4,4′-diphenylether dianhydride, bis(triphenylphthalic acid)-4,4′-diphenylmethane dianhydride, 9,9-bis(3,4-dicarboxyphenyl)fluorene dianhydride, 9,9-bis[4-(3,4-dicarboxyphenoxy)phenyl]fluorene dianhydride, 3,4-dicarboxy-1,2,3,4-tetrahydro-1-naphthalenesuccinic acid dianhydride, and 3,4-dicarboxy-1,2,3,4-tetrahydro-6-methyl-1-naphthalenesuccinic acid dianhydride.

Specific examples of the group including an aromatic carboxyl group represented by Ar¹ include a group represented by Formula (Ar-1), a group represented by Formula (Ar-2), and a group represented by Formula (Ar-3).

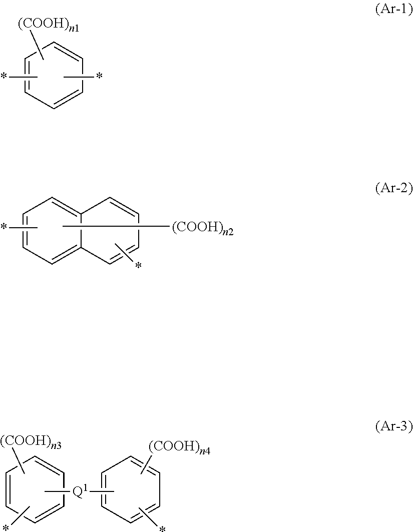

In Formula (Ar-1), n1 represents an integer of 1 to 4, and is preferably an integer of 1 or 2 and more preferably 2.

In Formula (Ar-2), n2 represents an integer of 1 to 8, and is preferably an integer of 1 or 4, more preferably 1 or 2, and still more preferably 2.

In Formula (Ar-3), n3 and n4 each independently represent an integer of 0 to 4, and are preferably an integer of 0 or 2, more preferably 1 or 2, and still more preferably 1. However, at least one of n3 or n4 is an integer of 1 or more.

In Formula (Ar-3), Q¹ represents a single bond, —O—, —CO—, —COOCH₂CH₂OCO—, —SO₂—, —C(CF₃)₂—, the above-described group represented by Formula (Q-1), or the above-described group represented by Formula (Q-2).

In Formula (b-1), L¹ represents —COO— or —CONH—, preferably —COO—.

In Formula (b-1), examples of the divalent linking group represented by L² include an alkylene group, an arylene group, —O—, —CO—, —COO—, —OCO—, —NH—, —S—, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10. The alkylene group and the arylene group may have a substituent. Examples of the substituent include a hydroxy group. The divalent linking group represented by L² is preferably a group represented by —O-L^{2a}-O—. Examples of L^{2a} include an alkylene group; an arylene group; a group formed by a combination of an alkylene group and an arylene group; and a group formed by a combination of at least one selected from an alkylene group and an arylene group, and at least one selected from —O—, —CO—, —COO—, —OCO—, —NH—, and —S—. The number of carbon atoms in the alkylene group preferably is 1 to 30, more preferably 1 to 20, and still more preferably 1 to 15. The alkylene group may be linear, branched, or cyclic. The alkylene group and the arylene group may have a substituent. Examples of the substituent include a hydroxy group.

Next, Formula (b-10) will be described. In Formula (b-10), the group including an aromatic carboxyl group, represented by Ar¹⁰, has the same meaning as Ar¹ in Formula (b-1), and the preferred range is also the same.

In Formula (b-10), L¹¹ represents —COO— or —CONH—, preferably —COO—.

In Formula (b-10), examples of the trivalent linking group represented by L¹² include a hydrocarbon group, —O—, —CO—, —COO—, —OCO—, —NH—, —S—, and a group formed by a combination of two or more of these groups. Examples of the hydrocarbon group include an aliphatic hydrocarbon group and an aromatic hydrocarbon group. The number of carbon atoms in the aliphatic hydrocarbon group is preferably 1 to 30, more preferably 1 to 20, and still more preferably 1 to 15. The aliphatic hydrocarbon group may be linear, branched, or cyclic. The number of carbon atoms in the aromatic hydrocarbon group is preferably 6 to 30, more preferably 6 to 20, and still more preferably 6 to 10. The hydrocarbon group may have a substituent. Examples of the substituent include a hydroxy group. The trivalent linking group represented by L¹² is preferably a group represented by Formula (L12-1), and more preferably a group represented by Formula (L12-2).

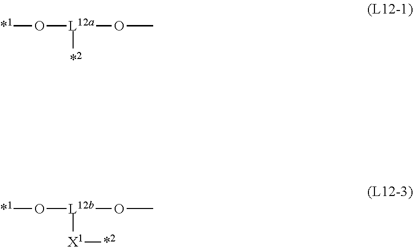

L^{12a} and L^{12b} each represent a trivalent linking group, X¹ represents S, *1 represents a bonding position with L¹¹ in Formula (b-10), and *2 represents a bonding position with P¹⁰ in Formula (b-10).

Examples of the trivalent linking group represented by L^{12a} and L^{12b} include a hydrocarbon group; and a group formed by a combination of a hydrocarbon group and at least one selected from —O—, —CO—, —COO—, —OCO—, —NH—, and —S—.

In Formula (b-10), P¹⁰ represents a polymer chain. It is preferable that the polymer chain represented by P¹⁰ has at least one repeating unit selected from a poly(meth)acrylic repeating unit, a polyether repeating unit, a polyester repeating unit, or a polyol repeating unit. The weight-average molecular weight of the polymer chain P¹⁰ is preferably 500 to 20000. The lower limit is preferably 500 or more and more preferably 1000 or more. The upper limit is preferably 10000 or less, more preferably 5000 or less, and still more preferably 3000 or less. In a case where the weight-average molecular weight of P¹⁰ is within the above-described range, dispersibility of the pigment in the composition is good. In a case where the resin B is a resin having the repeating unit represented by Formula (b-10), the resin B is preferably used as a dispersant.

In Formula (b-10), the polymer chain represented by P¹⁰ is preferably a polymer chain including a repeating unit represented by Formulae (P-1) to (P-5), and more preferably a polymer chain including a repeating unit represented by Formulae (P-5).

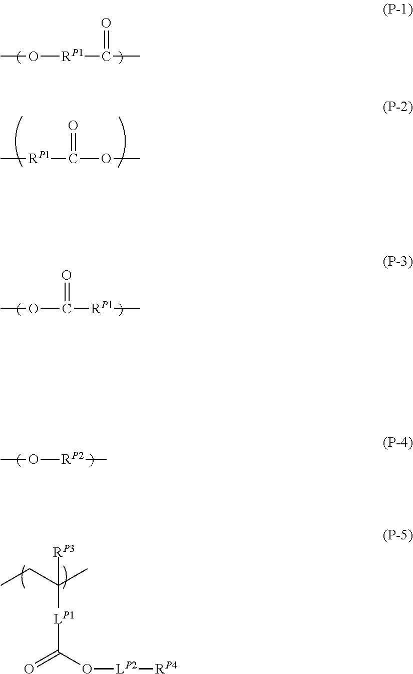

In the formulae, R^{P1} and R^{P2} each represent an alkylene group. As the alkylene group represented by R^{P1} and R^{P2}, a linear or branched alkylene group having 1 to 20 carbon atoms is preferable, a linear or branched alkylene group having 2 to 16 carbon atoms is more preferable, and a linear or branched alkylene group having 3 to 12 carbon atoms is still more preferable.

In the formulae, R^{P3} represents a hydrogen atom or a methyl group.

In the formulae, L^{P1} represents a single bond or an arylene group and L^{P2} represents a single bond or a divalent linking group. L^{P1} is preferably a single bond. Examples of the divalent linking group represented by L^{P2} include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, —NHCO—, —CONH—, and a group formed by a combination of two or more these groups.

R^{P4} represents a hydrogen atom or a substituent. Examples of the substituent include a hydroxy group, a carboxyl group, an alkyl group, an aryl group, a heteroaryl group, an alkoxy group, an aryloxy group, a heteroaryloxy group, an alkylthioether group, an arylthioether group, a heteroarylthioether group, a (meth)acryloyl group, an oxetanyl group, and a blocked isocyanate group. The blocked isocyanate group in the present invention is a group capable of generating an isocyanate group by heat, and preferred examples thereof include a group in which an isocyanate group is protected by reacting a blocking agent and an isocyanate group. Examples of the blocking agent include oxime compounds, lactam compounds, phenol compounds, alcohol compounds, amine compounds, active methylene compounds, pyrazole compounds, mercaptan compounds, imidazole compounds, and imide compounds. Examples of the blocking agent include compounds described in paragraphs “0115” to “0117” of JP2017-067930A, the contents of which are incorporated herein by reference. In addition, the blocked isocyanate group is preferably a group capable of generating an isocyanate group by heat of 90° C. to 260° C.

It is preferable that the polymer chain represented by P¹⁰ has at least one group (hereinafter, also referred to as a functional group A) selected from a (meth)acryloyl group, an oxetanyl group, a blocked isocyanate group, and a t-butyl group. The functional group A is more preferably at least one selected from a (meth)acryloyl group, an oxetanyl group, and a blocked isocyanate group. In a case where the polymer chain includes the functional group A, it is easy to form a film having excellent solvent resistance. In particular, the effects described above are remarkable in a case of including at least one group selected from a (meth)acryloyl group, an oxetanyl group, and a blocked isocyanate group. In addition, in a case where the functional group A has a t-butyl group, it is preferable that the composition includes a compound having an epoxy group or an oxetanyl group. In a case where the functional group A has a blocked isocyanate group, it is preferable that the composition includes a compound having a hydroxyl group.

In addition, it is more preferable that the polymer chain represented by P¹⁰ is a polymer chain having a repeating unit including the above-described functional group A in the side chain. In addition, the proportion of the repeating unit including the above-described functional group A in the side chain with respect to total repeating units constituting P¹⁰ is preferably 5 mass % or more, more preferably 10 mass % or more, and still more preferably 20 mass % or more. The upper limit may be 100 mass %, and is preferably 90 mass % or less and still more preferably 60 mass % or less.

In addition, it is also preferable that the polymer chain represented by P¹⁰ has a repeating unit including an acid group. Examples of the acid group include a carboxyl group, a phosphoric acid group, a sulfo group, and a phenolic hydroxy group. According to this aspect, the dispersibility of the pigment in the composition can be further improved. Furthermore, developability can also be further improved. The proportion of the repeating unit including an acid group is preferably 1 to 30 mass %, more preferably 2 to 20 mass %, and still more preferably 3 to 10 mass %.

The resin B can be manufactured by reacting at least one acid anhydride selected from an aromatic tetracarboxylic acid anhydride and an aromatic tricarboxylic acid anhydride with a hydroxyl group-containing compound. Examples of the aromatic tetracarboxylic acid anhydride and the aromatic tricarboxylic acid anhydride include those described above. The hydroxyl group-containing compound is not particularly limited as long as it has a hydroxyl group in the molecule, but is preferably a polyol having two or more hydroxyl groups in the molecule. In addition, as the hydroxyl group-containing compound, it is also preferable to use a compound having two hydroxyl groups and one thiol group in the molecule. Examples of the compound having two hydroxyl groups and one thiol group in the molecule include 1-mercapto-1,1-methanediol, 1-mercapto-1,1-ethanediol, 3-mercapto-1,2-propanediol (thioglycerin), 2-mercapto-1,2-propanediol, 2-mercapto-2-methyl-1,3-propanediol, 2-mercapto-2-ethyl-1,3-propanediol, 1-mercapto-2,2-propanediol, 2-mercaptoethyl-2-methyl-1,3-propanediol, and 2-mercaptoethyl-2-ethyl-1,3-propanediol. Examples of other hydroxyl group-containing compounds include compounds described in paragraphs “0084” to “0095” of JP2018-101039A, the contents of which are incorporated herein by reference.

The molar ratio (acid anhydride group/hydroxyl group) of the acid anhydride group in the acid anhydride to the hydroxyl group in the hydroxyl group-containing compound is preferably 0.5 to 1.5.

In addition, the resin including the repeating unit represented by Formula (b-10) can be synthesized by the methods shown in the following synthesis methods (1) and (2).

[Synthesis Method (1)]

Producing method of radically polymerizing a polymerizable monomer having an ethylenically unsaturated group in the presence of a hydroxyl group-containing thiol compound (preferably a compound having two hydroxyl groups and one thiol group in the molecule) to synthesize a vinyl polymer having two hydroxyl groups in one terminal region, and reacting the synthesized vinyl polymer with one or more aromatic acid anhydride selected from the aromatic tetracarboxylic acid anhydride and the aromatic tricarboxylic acid anhydride.

[Synthesis Method (2)]

Producing method of reacting a hydroxyl group-containing compound (preferably a compound having two hydroxyl groups and one thiol group in the molecule) with one or more aromatic acid anhydride selected from the aromatic tetracarboxylic acid anhydride and the aromatic tricarboxylic acid anhydride, and radically polymerizing a polymerizable monomer having an ethylenically unsaturated group in the presence of the obtained reactant. In the synthesis method (2), after radically polymerizing the polymerizable monomer having a hydroxyl group, the reactant may be further reacted with a compound having an isocyanate group (for example, a compound having an isocyanate group and the above-described functional group A). As a result, the functional group A can be introduced into the polymer chain P¹⁰.

In addition, the resin B can also be synthesized according to the method described in paragraphs “0120” to “0138” of JP2018-101039A.

The weight-average molecular weight of the resin B is preferably 2000 to 35000. The upper limit is preferably 25000 or less, more preferably 20000 or less, and still more preferably 15000 or less. The lower limit is preferably 4000 or more, more preferably 6000 or more, and still more preferably 7000 or more. In a case where the weight-average molecular weight of the resin B is within the above-described range, the above-described effects are more remarkably obtained. In addition, storage stability of the coloring composition can also be improved.

The acid value of the resin B is preferably 5 to 200 mgKOH/g. The upper limit is preferably 150 mgKOH/g or less, more preferably 100 mgKOH/g or less, and still more preferably 80 mgKOH/g or less. The lower limit is preferably 10 mgKOH/g or more, more preferably 15 mgKOH/g or more, and still more preferably 20 mgKOH/g or more. In a case where the acid value of the resin B is within the above-described range, the above-described effects are more remarkably obtained. In addition, pigment adsorption ability can be appropriately obtained, and pigment dispersibility in the composition can be enhanced. Furthermore, the storage stability of the coloring composition can also be improved.

The coloring composition according to the embodiment of the present invention also preferably includes a resin (hereinafter, also referred to as a resin C) having a maleimide structure. In addition, in a case where the resin B and the resin C are used in combination, even in a case where the pigment concentration in the coloring composition is increased, color loss during development can be further suppressed. The reason why such an effect can be obtained is that the interaction between the resin B and the resin C works strongly, and the interactions between the pigment and the resin B, and between the pigment and the resin C work strongly. As a result, it is presumed that the pigment can be firmly retained in the film.

In the present specification, the maleimide structure is a structure derived from a maleimide compound. Examples of the maleimide compound include maleimide and N-substituted maleimide. Examples of the N-substituted maleimide include cyclohexylmaleimide, phenylmaleimide, methylmaleimide, ethylmaleimide, n-butylmaleimide, and laurylmaleimide. Among these, from the viewpoint that it is also good in developability, developer resistance, and the like, cyclohexylmaleimide or phenylmaleimide is particularly preferable.

The resin C is preferably a resin including a repeating unit having a maleimide structure. The maleimide structure may be included in the main chain of the repeating unit, or in the side chain of the repeating unit. From the reason that it is easy to form a film having excellent developability and color loss resistance, it is preferable that the maleimide structure is included in the main chain of the repeating unit. The content of the repeating unit having a maleimide structure with respect to total repeating units of the resin C is preferably 5 mol % or more, more preferably 10 mol % or more, and still more preferably 15 mol % or more. The upper limit is preferably 70 mol % or less, more preferably 60 mol % or less, and still more preferably 50 mol % or less. In a case where the content of the repeating unit having a maleimide structure is within the above-described range, it is easy to more effectively suppress color loss during development. Furthermore, excellent developability can be obtained.

The resin C in the present invention preferably includes at least one selected from a repeating unit represented by Formula (c-1) and a repeating unit represented by Formula (c-2), and more preferably includes a repeating unit represented by Formula (c-1).

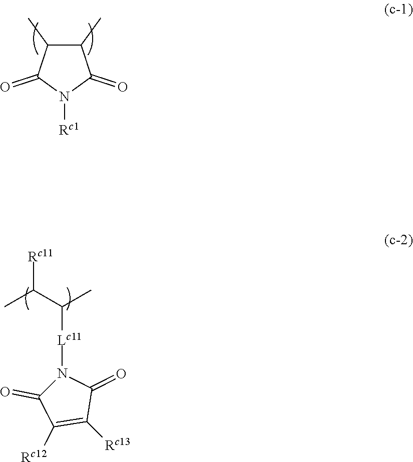

In Formula (c-1), R^{C1} represents a hydrogen atom, an alkyl group, or an aryl group. The number of carbon atoms in the alkyl group is preferably 1 to 20. The alkyl group may be linear, branched, or cyclic. The number of carbon atoms in the aryl group is preferably 6 to 20, more preferably 6 to 15, and still more preferably 6 to 10. R^{C1} is preferably an aryl group.

In Formula (c-2), L^{C11} represents a single bond or a divalent substituent. Examples of the divalent substituent include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, —NHCO—, —CONH—, and a group formed by a combination of two or more these groups.

In Formula (c-2), R^{C11} represents a hydrogen atom or a methyl group.

In Formula (c-2), R^{C12} and R^{C13} each independently represent a hydrogen atom or an alkyl group, and R^{C12} and R^{C13} may be linked to each other to form a ring. The number of carbon atoms in the alkyl group represented by R^{C12} and R^{C13} is preferably 1 to 20. The alkyl group may be linear, branched, or cyclic.

The resin C also preferably has a repeating unit including an acid group. Examples of the acid group include a carboxyl group, a phosphoric acid group, a sulfo group, and a phenolic hydroxy group, and a carboxyl group is preferable. According to this aspect, more excellent developability is easily obtained. In a case where the resin C has a repeating unit including an acid group, the content of the repeating unit including an acid group with respect to the total repeating units of the resin C is preferably 5 to 60 mol %. The lower limit is preferably 8 mol % or more, more preferably 10 mol % or more, and still more preferably 15 mol % or more. The upper limit is preferably 50 mol % or less, more preferably 40 mol % or less, and still more preferably 30 mol % or less.

The resin C also preferably has a repeating unit including a polymerizable group. Examples of the polymerizable group include ethylenically unsaturated groups (groups having an ethylenically unsaturated bond) such as a vinyl group, a (meth)allyl group, and a (meth)acryloyl group. According to this aspect, a film having excellent heat resistance and solvent resistance is easily obtained. In a case where the resin C has a repeating unit including a polymerizable group, the content of the repeating unit including a polymerizable group with respect to the total repeating units of the resin C is preferably 5 to 60 mol %. The lower limit is preferably 8 mol % or more, more preferably 10 mol % or more, and still more preferably 15 mol % or more. The upper limit is preferably 50 mol % or less, more preferably 40 mol % or less, and still more preferably 30 mol % or less.

The weight-average molecular weight of the resin C is preferably 2000 to 100000. The upper limit is preferably 40000 or less and more preferably 20000 or less. The lower limit is preferably 4000 or more and more preferably 6000 or more.

The acid value of the resin C is preferably 5 to 200 mgKOH/g. The upper limit is preferably 150 mgKOH/g or less, more preferably 100 mgKOH/g or less, and still more preferably 80 mgKOH/g or less. The lower limit is preferably 10 mgKOH/g or more, more preferably 15 mgKOH/g or more, and still more preferably 20 mgKOH/g or more. In a case where the acid value of the resin C is within the above-described range, the above-described effects are more remarkably obtained.

The coloring composition according to the embodiment of the present invention also preferably contains a resin (hereinafter, also referred to as a resin F) including a repeating unit (hereinafter, also referred to as a repeating unit f1-1) derived from a compound represented by Formula (I). In a case where the coloring composition according to the embodiment of the present invention further includes the resin F, it is possible to improve the developability while having excellent color loss resistance. The content of the repeating unit f1-1 with respect to total repeating units of the resin F is preferably 5 mol % or more, more preferably 10 mol % or more, and still more preferably 15 mol % or more.

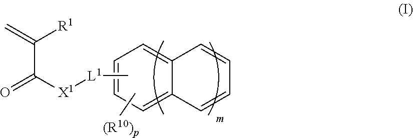

X¹ represents O or NH, and is preferably O.

R¹ represents a hydrogen atom or a methyl group.

L¹ represents a divalent linking group. Examples of the divalent linking group include a hydrocarbon group, a heterocyclic group, —NH—, —SO—, SO₂—, —CO—, —O—, —COO—, —OCO—, —S—, and a group formed by a combination of two or more of these groups. Examples of the hydrocarbon group include an alkyl group and an aryl group. The heterocyclic group may be a non-aromatic heterocyclic group or an aromatic heterocyclic group. The heterocyclic group is preferably a 5-membered ring or a 6-membered ring. Examples of the kind of the heteroatom constituting the heterocyclic group include a nitrogen atom, an oxygen atom, and a sulfur atom. The number of heteroatoms constituting the heterocyclic group is preferably 1 to 3. The heterocyclic group may be a single ring or a fused ring. The hydrocarbon group and heterocyclic group may have a substituent. Examples of the substituent include an alkyl group, an aryl group, a hydroxy group, and a halogen atom.

R¹⁰ represents a substituent. Examples of the substituent represented by R¹⁰ include the substituent T shown below, and the substituent represented by R¹⁰ is preferably a hydrocarbon group and more preferably an alkyl group which may have an aryl group as a substituent.

m represents an integer of 0 to 2, and is preferably 0 or 1 and more preferably 0.

p represents an integer of 0 or more, preferably 0 to 4, more preferably 0 to 3, still more preferably 0 to 2, even more preferably 0 or 1, and particularly preferably 1.

(Substituent T)

Examples of a substituent T include a halogen atom, a cyano group, a nitro group, a hydrocarbon group, a heterocyclic group, —ORt¹, —CORt¹, —COORt¹, —OCORt¹, —NRt¹Rt², —NHCORt¹, —CONRt¹Rt², —NHCONRt¹Rt², —NHCOORt¹, —SRt¹, —SO₂Rt¹, —SO₂ORt¹, —NHSO₂Rt¹, and —SO₂NRt¹Rt². Rt¹ and Rt² each independently represent a hydrogen atom, a hydrocarbon group, or a heterocyclic group. Rt¹ and Rt² may be bonded to each other to form a ring.

Examples of the halogen atom include a fluorine atom, a chlorine atom, a bromine atom, and an iodine atom.

Examples of the hydrocarbon group include an alkyl group, an alkenyl group, an alkynyl group, and an aryl group. The number of carbon atoms in the alkyl group is preferably 1 to 30, more preferably 1 to 15, and still more preferably 1 to 8. The alkyl group may be linear, branched, or cyclic, and is preferably linear or branched and more preferably branched.

The number of carbon atoms in the alkenyl group is preferably 2 to 30, more preferably 2 to 12, and particularly preferably 2 to 8. The alkenyl group may be linear, branched, or cyclic, and is preferably linear or branched.

The number of carbon atoms of the alkynyl group is preferably 2 to 30 and more preferably 2 to 25. The alkynyl group may be linear, branched, or cyclic, and is preferably linear or branched.

The number of carbon atoms in the aryl group is preferably 6 to 30, more preferably 6 to 20, and still more preferably 6 to 12.

The heterocyclic group may be a single ring or a fused ring. The heterocyclic group is preferably a single ring or a fused ring having 2 to 4 fused rings. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12.

The hydrocarbon group and the heterocyclic group may have a substituent or may be unsubstituted. Examples of the substituent include the substituents described in the substituent T.

The compound represented by Formula (I) is preferably a compound represented by Formula (I-1).

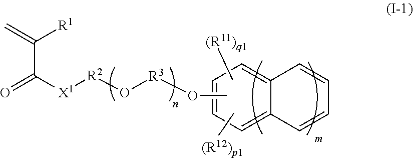

X¹ represents O or NH, and is preferably O.

R¹ represents a hydrogen atom or a methyl group.

R², R³, and R¹¹ each independently represent a hydrocarbon group.

The hydrocarbon group represented by R² and R³ is preferably an alkylene group or an arylene group, and more preferably an alkylene group. The number of carbon atoms in the alkylene group is preferably 1 to 10, more preferably 1 to 5, still more preferably 1 to 3, and particularly preferably 2 or 3. The hydrocarbon group represented by R¹¹ is preferably an alkyl group which may have an aryl group as a substituent, and more preferably an alkyl group having an aryl group as a substituent. The number of carbon atoms in the alkyl group is preferably 1 to 20, more preferably 1 to 10, and still more preferably 1 to 5. The number of carbon atoms in the alkyl group in a case where the alkyl group has an aryl group as a substituent means the number of carbon atoms in an alkyl moiety.

R¹² represents a substituent. Examples of the substituent represented by R¹² include the above-described substituent T.

n represents an integer of 0 to 15, and is preferably an integer of 0 or 5, more preferably an integer of 0 to 4, and still more preferably an integer of 0 to 3.

m represents an integer of 0 to 2, preferably 0 or 1 and more preferably 0.

p1 represents an integer of 0 or more, preferably 0 to 4, more preferably 0 to 3, still more preferably 0 to 2, even more preferably 0 or 1, and particularly preferably 0.

q1 represents an integer of 1 or more, preferably 1 to 4, more preferably 1 to 3, still more preferably 1 to 2, and particularly preferably 1.

The compound represented by Formula (I) is preferably a compound represented by Formula (III).

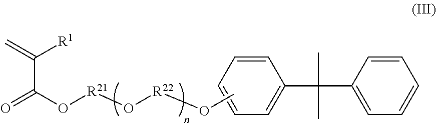

In the formula, R¹ represents a hydrogen atom or a methyl group, R²¹ and R²² each independently represent an alkylene group, and n represents an integer of 0 to 15. The number of carbon atoms in the alkylene group represented by R²¹ and R²² is preferably 1 to 10, more preferably 1 to 5, still more preferably 1 to 3, and particularly preferably 2 or 3. n represents an integer of 0 to 15, and is preferably an integer of 0 or 5, more preferably an integer of 0 to 4, and still more preferably an integer of 0 to 3.

Examples of the compound represented by Formula (I) include ethylene oxide- or propylene oxide-modified (meth)acrylate of para-cumylphenol. Examples of a commercially available product thereof include ARONIX M-110 (manufactured by TOAGOSEI CO., LTD,).

It is preferable that the resin F further includes a repeating unit (hereinafter, also referred to as a repeating unit f1-2) derived from an alkyl (meth)acrylate. In a case where the resin F further has the repeating unit f1-2, the effect of improving solvent solubility is obtained. The number of carbon atoms in an alkyl moiety of the alkyl (meth)acrylate is preferably 3 to 10, more preferably 3 to 8, and still more preferably 3 to 6. Preferred specific examples of the alkyl (meth)acrylate include n-butyl (meth)acrylate, ethyl (meth)acrylate, and 2-ethylhexyl acrylate. From the reason that it is easy to obtain more excellent solvent solubility, n-butyl (meth)acrylate is preferable. The content of the repeating unit f1-2 with respect to total repeating units of the resin F is preferably 5 mol % or more, more preferably 10 mol % or more, and still more preferably 15 mol % or more.

It is also preferable that the resin F further includes a repeating unit (hereinafter, also referred to as a repeating unit f1-3) having an acid group. According to this aspect, the effect of improving developability is obtained. The content of the repeating unit f1-3 with respect to total repeating units of the resin F is preferably 5 mol % or more, more preferably 10 mol % or more, and still more preferably 15 mol % or more. The upper limit is preferably 60 mol % or less and more preferably 50 mol % or less.

It is also preferable that the resin F further includes a repeating unit (hereinafter, also referred to as a repeating unit f1-4) having a polymerizable group. The content of the repeating unit f1-4 with respect to total repeating units of the resin F is preferably 5 mol % or more, more preferably 10 mol % or more, and still more preferably 15 mol % or more. The upper limit is preferably 50 mol % or less and more preferably 40 mol % or less.

The coloring composition according to the embodiment of the present invention can include a resin (hereinafter, also referred to as other resins) other than the above-described resin B, resin C, and resin F.

The other resins are also preferably a resin having an acid group. Examples of the acid group include a carboxyl group, a phosphoric acid group, a sulfo group, and a phenolic hydroxy group. The resin having an acid group can also be used as an alkali-soluble resin or a dispersant. The acid value of the resin having an acid group is preferably 30 to 500 mgKOH/g. The lower limit is more preferably 50 mgKOH/g or more and still more preferably 70 mgKOH/g or more. The upper limit is more preferably 400 mgKOH/g or less, still more preferably 200 mgKOH/g or less, particularly preferably 150 mgKOH/g or less, and most preferably 120 mgKOH/g or less.

As the other resins, a resin including a repeating unit derived from a compound represented by Formula (ED1) and/or a compound represented by Formula (ED2) (hereinafter, these compounds will also be referred to as an “ether dimer”) is also preferable.

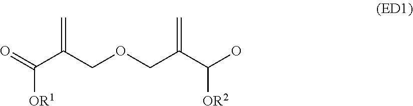

In Formula (ED1), R¹ and R² each independently represent a hydrogen atom or a hydrocarbon group having 1 to 25 carbon atoms, which may have a substituent.

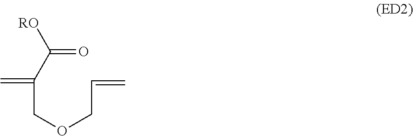

In Formula (ED2), R represents a hydrogen atom or an organic group having 1 to 30 carbon atoms. Specific examples of Formula (ED2) can be found in the description of JP2010-168539A.

Specific examples of the ether dimer can be found in paragraph “0317” of JP2013-029760A, the contents of which are incorporated herein by reference.

The other resins are also preferably a resin including a repeating unit having a polymerizable group. By using a resin including a repeating unit having a polymerizable group, it is possible to form a film having excellent color loss resistance, solvent resistance, and heat resistance. Examples of the polymerizable group include ethylenically unsaturated groups such as a vinyl group, a (meth)allyl group, and a (meth)acryloyl group.

The coloring composition according to the embodiment of the present invention can contain a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total content of the acid group and the basic group is 100 mol %, and more preferably a resin substantially consisting of only an acid group. The acid group in the acidic dispersant (acidic resin) is preferably a carboxyl group. The acid value of the acidic dispersant (acidic resin) is preferably 10 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

It is preferable that the resin used as a dispersant includes a repeating unit having an acid group. In a case where the resin used as a dispersant includes a repeating unit having an acid group, the generation of the development residue can be further suppressed in the formation of a pattern by a photolithography method.

It is also preferable that the resin used as a dispersant is a graft resin. With regard to details of the graft resin, reference can be made to the description in paragraphs “0025” to “0094” of JP2012-255128A, the contents of which are incorporated herein by reference.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraphs “0102” to “0166” of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraphs “0196” to “0209” of JP2013-043962A.

It is also preferable that the resin used as a dispersant is a resin including a repeating unit having an ethylenically unsaturated group in the side chain. The content of the repeating unit having an ethylenically unsaturated group in the side chain is preferably 10 mol % or more, more preferably 10 to 80 mol %, and still more preferably 20 to 70 mol % with respect to all the repeating units of the resin.

A commercially available product is also available as the dispersant, and specific examples thereof include DISPERBYK series (for example, DISPERBYK-111, 2001, and the like) manufactured by BYK Chemie, Solsperse series (for example, Solsperse 20000, 76500, and the like) manufactured by Lubrizol Corporation, and AJISPER series manufactured by Ajinomoto Fine-Techno Co., Inc. In addition, products described in paragraph “0129” of JP2012-137564A and products described in paragraph “0235” of JP2017-194662A can also be used as the dispersant. In addition, the above-described resin B can also be used as the dispersant.

The content of the resin in the total solid content of the coloring composition is preferably 10% to 50 mass %. The upper limit is preferably 40 mass % or less and more preferably 30 mass % or less. The lower limit is preferably 15 mass % or more and more preferably 20 mass % or more.

It is preferable that the resin included in the coloring composition according to the embodiment of the present invention includes the resin having an acid group. In addition, the content of the resin having an acid group in the resin included in the coloring composition according to the embodiment of the present invention is preferably 50 to 100 mass %, more preferably 75 to 100 mass %, still more preferably 80 to 100 mass %, even more preferably 90 to 100 mass %, and particularly preferably 95 to 100 mass %.

In a case where the coloring composition according to the embodiment of the present invention includes the resin as a dispersant, the content of the resin as the dispersant is preferably 10 to 100 parts by mass with respect to 100 parts by mass of the pigment. The upper limit is preferably 80 parts by mass or less and more preferably 60 parts by mass or less. The lower limit is preferably 15 parts by mass or more and more preferably 20 parts by mass or more.

In addition, the content of the resin as the dispersant is preferably 10 to 100 parts by mass with respect to 100 parts by mass in total of the pigment and the pigment derivative. The upper limit is preferably 80 parts by mass or less and more preferably 60 parts by mass or less. The lower limit is preferably 15 parts by mass or more and more preferably 20 parts by mass or more. In addition, in a case where the resin B is used as a dispersant, the content of the resin B in the total amount of the dispersant is preferably 10 to 100 mass %, more preferably 30 to 100 mass %, and still more preferably 50 to 100 mass %.

In addition, in a case where the coloring composition according to the embodiment of the present invention includes the above-described resin B and resin C, the total content of the resin B and the resin C in the resins included in the coloring composition according to the embodiment of the present invention is preferably 10 to 50 mass %. The upper limit is preferably 40 mass % or less and more preferably 30 mass % or less. The lower limit is preferably 15 mass % or more and more preferably 20 mass % or more. In addition, the content of the resin C is preferably 5 to 100 parts by mass with respect to 100 parts by mass of the resin B. The lower limit is preferably 10 parts by mass or more and more preferably 20 parts by mass or more. The upper limit is preferably 70 parts by mass or less and still more preferably 50 parts by mass or less.

In addition, in a case where the coloring composition according to the embodiment of the present invention includes the above-described resin F, the total content of the resin F with respect to the total amount of resins included in the coloring composition according to the embodiment of the present invention is preferably 1 to 50 mass %. The upper limit is preferably 40 mass % or less and more preferably 30 mass % or less. The lower limit is preferably 2 mass % or more and more preferably 5 mass % or more.

«Solvent»

The coloring composition according to the embodiment of the present invention contains a solvent. Examples of the solvent include an organic solvent. Examples of the organic solvent include an ester solvent, a ketone solvent, an alcohol solvent, an amide solvent, an ether solvent, and a hydrocarbon solvent. The details of the organic solvent can be found in paragraph “0223” of WO2015/166779A, the contents of which are incorporated herein by reference.

The coloring composition according to the embodiment of the present invention contains a solvent (hereinafter, also referred to as a solvent D1) having a solubility parameter (SP value) of 18.0 to 26.0 MPa^{0.5}. By using the solvent D1, it is possible to effectively suppress coarsening due to aggregation of the pigment derivative and the like.

The lower limit of the SP value of the solvent D1 is preferably 19.0 MPa^{0.5} or more, more preferably 20.0 MPa^{0.5} or more, and still more preferably 21.0 MPa^{0.5} or more. The upper limit thereof is preferably 25.0 MPa^{0.5} or less, more preferably 24.0 MPa^{0.5} or less, and still more preferably 23.0 MPa^{0.5} or less.

Examples of the solvent D1 include an alcohol solvent, an ether solvent, an ester solvent, and a ketone solvent. Specific examples of the solvent D1 include cyclohexanone, 2-butanol, and propylene glycol monomethyl ether.

It is preferable that the coloring composition according to the embodiment of the present invention includes a solvent (hereinafter, solvent D2) having an SP value of less than 18 MPa^{0.5}. By using the solvent D1 and the solvent D2 in combination, both the affinity between the pigment derivative and the solvents and adsorptivity between the pigment and the pigment derivative can be achieved at a high level, and the effects of the present invention are obtained more remarkably.

The lower limit of the SP value of the solvent D2 is preferably 16 MPa^{0.5} or more, more preferably 16.5 MPa^{0.5} or more, and still more preferably 17 MPa^{0.5} or more. The upper limit thereof is preferably 17.8 MPa^{0.5} or less and more preferably 17.6 MPa^{0.5} or less.

Examples of the solvent D2 include an alcohol solvent, an ether solvent, an ester solvent, and a ketone solvent. Specific examples of the solvent D2 include propylene glycol monomethyl ether acetate and butyl acetate.

In a case where the solvent D1 and the solvent D2 are used in combination, the content of the solvent D2 is preferably 500 to 5000 parts by mass with respect to 100 parts by mass of the solvent D1. The lower limit is preferably 800 parts by mass or more and more preferably 1000 parts by mass or more. The upper limit is preferably 4000 parts by mass or less and more preferably 3000 parts by mass or less.

The content of the solvent in the coloring composition is preferably 10 to 95 mass %, more preferably 20 to 90 mass %, and still more preferably 30 to 90 mass %.

In addition, the content of the above-described solvent D1 with respect to the total amount of the solvent included in the coloring composition is preferably 4 mass % or more, more preferably 5 mass % or more, and still more preferably 6 mass % or more. The upper limit may be 100 mass %, 50 mass % or less, or 20 mass % or less.

In a case where the solvent D1 and the solvent D2 are used in combination as the solvent, the total content of the solvent D1 and the solvent D2 with respect to the total amount of the solvent included in the coloring composition is preferably 50 mass % or more, more preferably 60 mass % or more, and still more preferably 70 mass % or more. The upper limit may be 100 mass %.

The solvent used in the present invention is also preferably a solvent having a low metal content. For example, the metal content of the solvent is preferably 10 ppb (parts per billion) by mass or less. Optionally, a solvent having a metal content at a mass parts per trillion (ppt) level may be used. For example, such a solvent is available from Toyo Gosei Co., Ltd. (The Chemical Daily, Nov. 13, 2015). Examples of a method for removing impurities such as a metal from the solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

«Polymerizable Monomer»

It is preferable that the coloring composition according to the embodiment of the present invention contains a polymerizable monomer. Examples of the polymerizable monomer include a compound having an ethylenically unsaturated group. Examples of the ethylenically unsaturated group include a vinyl group, a (meth)allyl group, and a (meth)acryloyl group. The polymerizable monomer is preferably a compound (radical polymerizable monomer) which can be polymerized by radicals.

It is preferable that the polymerizable monomer is a compound including three or more ethylenically unsaturated groups. The upper limit of the ethylenically unsaturated group is preferably 15 or less, more preferably 10 or less, and still more preferably 6 or less. In addition, as the polymerizable monomer, a (meth)acrylate compound having 3 or more functional groups is preferable, a (meth)acrylate compound having 3 to 15 functional groups is more preferable, a (meth)acrylate compound having 3 to 10 functional groups is still more preferable, and a (meth)acrylate compound having 3 to 6 functional groups is particularly preferable.

The molecular weight of the polymerizable monomer is preferably 100 to 2000. The upper limit is preferably 1500 or less, more preferably 1000 or less, still more preferably 450 or less, and particularly preferably 400 or less. The lower limit is preferably 150 or more.

From the viewpoint of temporal stability of the composition and color loss resistance of a film to be obtained, an ethylenically unsaturated group value (hereinafter, referred to as a C═C value) of the polymerizable monomer is preferably 2 to 14 mmol/g. The lower limit is preferably 3 mmol/g or more, more preferably 4 mmol/g or more, and still more preferably 5 mmol/g or more. The upper limit is preferably 12 mmol/g or less, more preferably 10 mmol/g or less, and still more preferably 8 mmol/g or less. The C═C value of the polymerizable monomer is obtained by dividing the number of ethylenically unsaturated groups included in one molecule of the polymerizable monomer by the molecular weight of the polymerizable monomer.

The polymerizable monomer used in the present invention is also preferably a compound including three or more ethylenically unsaturated groups, more preferably a compound including three ethylenically unsaturated groups, and still more preferably a trifunctional (meth)acrylate compound. According to this aspect, solvent resistance of a film to be obtained can be further improved. The detailed reason for obtaining such an effect is not clear, but it is presumed that a very dense network structure can be formed by exposure. Examples of the polymerizable monomer including three ethylenically unsaturated groups include trimethylolpropane triacrylate, tris(2-acryloyloxyethyl) isocyanurate, and trimethylolpropane ethylene-modified triacrylate.

The polymerizable monomer used in the present invention is also preferably a compound having an isocyanurate skeleton. By using a polymerizable monomer having an isocyanurate skeleton, solvent resistance of a film to be obtained can be improved.

The polymerizable monomer having an isocyanurate skeleton is preferably a compound represented by Formula (Mi-1). * in the formula is a linking hand.

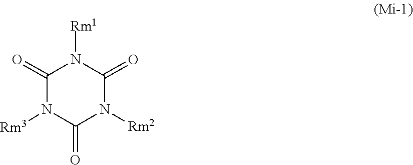

Rm¹ to Rm³ are each independently a group represented by any one of Formulae (Rm-1) to (Rm-5), and at least one of Rm¹ to Rm³ is a group represented by any one of Formulae (Rm-1) to (Rm-4).

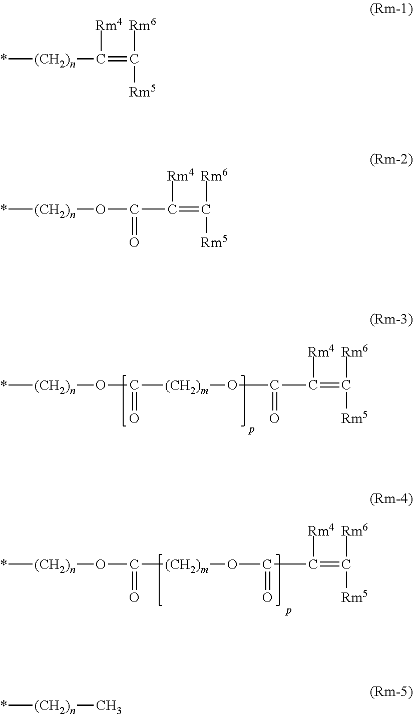

In the formulae, Rm⁴ to Rm⁶ each independently represent a hydrogen atom or a methyl group, n and m each independently represent an integer of 1 to 20, p represents an integer of 1 to 5, and * represents a bonding hand.

Specific examples of the polymerizable monomer having an isocyanurate skeleton include tris(2-acryloyloxyethyl) isocyanurate and ε-caprolactone-modified tris(2-acryloxyethyl) isocyanurate. Examples of a commercially available product thereof include FANCRYL FA-731A (manufactured by Hitachi Chemical Co., Ltd.), NK ESTER A-9300, A-9300-1CL, and A9300-3CL (manufactured by Shin-Nakamura Chemical Co., Ltd.), and ARONIX M-315 (manufactured by TOAGOSEI CO., LTD.).

In the present invention, as the polymerizable monomer, dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), a compound having a structure in which the (meth)acryloyl group of these compounds is bonded through an ethylene glycol and/or a propylene glycol residue (for example, SR454 and SR499 which are commercially available from Sartomer), and the like can also be used. In addition, as the polymerizable monomer, ARONIX M-400 and M-402 (manufactured by TOAGOSEI CO., LTD.; a mixture of dipentaerythritol hexaacrylate and dipentaerythritol pentaacrylate) can also be preferably used.

In the present invention, it is also preferable to use a polymerizable monomer having an acid group as the polymerizable monomer. By using a polymerizable monomer having an acid group, a coloring composition layer in an unexposed area is easily removed during development and the generation of the development residue can be suppressed. Examples of the acid group include a carboxyl group, a sulfo group, and a phosphoric acid group, and a carboxyl group is preferable. Examples of the polymerizable monomer having an acid group include succinic acid-modified dipentaerythritol penta(meth)acrylate. Examples of a commercially available product of the polymerizable monomer having an acid group include ARONIX M-510, M-520, and ARONIX TO-2349 (manufactured by TOAGOSEI CO., LTD.). The acid value of the polymerizable monomer having an acid group is preferably 0.1 to 40 mgKOH/g and more preferably 5 to 30 mgKOH/g. In a case where the acid value of the polymerizable monomer is 0.1 mgKOH/g or more, solubility in a developer is good, and in a case where the acid value of the polymerizable monomer is 40 mgKOH/g or less, it is advantageous in production and handling.

In the present invention, it is also preferable to use a compound having a caprolactone structure as the polymerizable monomer. Examples of the polymerizable monomer having a caprolactone structure include DPCA-20, DPCA-30, DPCA-60, and DPCA-120, each of which is commercially available as KAYARAD DPCA series from Nippon Kayaku Co., Ltd.

As the polymerizable monomer, it is also preferable to use compounds described in JP2017-048367A, JP6057891B, and JP6031807B, compounds described in JP2017-194662A, 8UH-1006 and 8UH-1012 (both of which are manufactured by Taisei Fine Chemical Co., Ltd.), Light Acrylate POB-AO (manufactured by Kyoeisha Chemical Co., Ltd.), and the like.

In a case where the coloring composition according to the embodiment of the present invention contains a polymerizable monomer, the content of the polymerizable monomer in the total solid content of the coloring composition is preferably 2 to 30 mass %. The upper limit is preferably 20 mass % or less and more preferably 10 mass % or less. The lower limit is preferably 3 mass % or more and more preferably 5 mass % or more. The polymerizable monomer contained in the coloring composition may be only one kind or two or more kinds thereof. In a case of using two or more kinds thereof, the total content thereof is preferably within the above-described range.

In addition, the total content of the resin and the polymerizable monomer in the total solid content of the coloring composition is preferably 10 to 50 mass %. The lower limit is preferably 15 mass % or more, more preferably 20 mass % or more, and still more preferably 25 mass % or more. The upper limit is preferably 45 mass % or less, more preferably 40 mass % or less, and still more preferably 35 mass % or less.

«Compound Having Epoxy Group»

The coloring composition according to the embodiment of the present invention can further contain a compound having an epoxy group (hereinafter, also referred to as an epoxy compound). Examples of the epoxy compound include a compound having one or more epoxy groups in one molecule, and a compound having two or more epoxy groups in one molecule is preferable. The epoxy compound preferably has 1 to 100 epoxy groups in one molecule. The upper limit of the number of epoxy groups may be, for example, 10 or less or 5 or less. The lower limit of the number of epoxy groups is preferably 2 or more. As the epoxy compound, compounds described in paragraphs “0034” to “0036” of JP2013-11869A, paragraphs “0147” to “0156” of JP2014-043556A, and paragraphs “0085” to “0092” of JP2014-089408A, and compounds described in JP2017-179172A can also be used. The contents thereof are incorporated herein by reference.

The epoxy compound may be a low-molecular-weight compound (for example, having a molecular weight of less than 2000, and further, a molecular weight of less than 1000) or a high-molecular-weight compound (macromolecule) (for example, having a molecular weight of 1000 or more, and in a case of a polymer, having a weight-average molecular weight of 1000 or more). The weight-average molecular weight of the epoxy compound is preferably 200 to 100000 and more preferably 500 to 50000. The upper limit of the weight-average molecular weight is preferably 10000 or less, more preferably 5000 or less, and still more preferably 3000 or less.

Examples of a commercially available product of the epoxy compound include EHPE3150 (manufactured by Daicel Corporation) and EPICLON N-695 (manufactured by DIC Corporation).

In a case where the coloring composition according to the embodiment of the present invention contains an epoxy compound, the content of the epoxy compound in the total solid content of the coloring composition is preferably 0.1 to 20 mass %. The lower limit is, for example, preferably 0.5 mass % or more, and more preferably 1 mass % or more. The upper limit is, for example, preferably 15 mass % or less and still more preferably 10 mass % or less. The epoxy compound contained in the coloring composition may be only one kind or two or more kinds thereof. In a case of using two or more kinds thereof, the total content thereof is preferably within the above-described range.

«Photopolymerization Initiator»

It is preferable that the coloring composition according to the embodiment of the present invention includes a photopolymerization initiator. In particular, in a case where the coloring composition according to the embodiment of the present invention includes the polymerizable compound, it is preferable that the coloring composition according to the embodiment of the present invention further includes a photopolymerization initiator. The photopolymerization initiator is not particularly limited, and can be appropriately selected from known photopolymerization initiators. For example, a compound having photosensitivity to light ray in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, and an acylphosphine compound is more preferable, and an oxime compound is still more preferable. The details of the photopolymerization initiator can be found in paragraphs “0065” to “0111” of JP2014-130173A and in JP6301489B, the contents of which are incorporated herein by reference.

Examples of a commercially available product of the α-hydroxyketone compound include IRGACURE-184, DAROCUR-1173, IRGACURE-500, IRGACURE-2959, and IRGACURE-127 (all of which are manufactured by BASF). Examples of a commercially available product of the α-aminoketone compound include IRGACURE-907, IRGACURE-369, IRGACURE-379, and IRGACURE-379EG (all of which are manufactured by BASF). Examples of a commercially available product of the acylphosphine compound include IRGACURE-819 and DAROCUR-TPO (both of which are manufactured by BASF).

Examples of the oxime compound include compounds described in JP2001-233842A, compounds described in JP2000-080068A, compounds described in JP2006-342166A, compounds described in J. C. S. Perkin II (1979, pp. 1653-1660), compounds described in J. C. S. Perkin II (1979, pp. 156-162), compounds described in Journal of Photopolymer Science and Technology (1995, pp. 202-232), compounds described in JP2000-066385A, compounds described in JP2004-534797A, compounds described in JP2006-342166A, compounds described in JP2017-019766A, compounds described in JP6065596B, compounds described in WO2015/152153A, compounds described in WO2017/051680A, compounds described in JP2017-198865A, and compounds described in paragraphs “0025” to “0038” of WO2017/164127A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include IRGACURE-OXE01, IRGACURE-OXE02, IRGACURE-OXE03, and IRGACURE-OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no coloring property or a compound having high transparency and being resistant to discoloration. Examples of a commercially available product thereof include ADEKA ARKLS NCI-730, NCI-831, and NCI-930 (all of which are manufactured by ADEKA Corporation).

In the present invention, an oxime compound having a fluorene ring can also be used as the photopolymerization initiator. Specific examples of the oxime compound having a fluorene ring include compounds described in JP2014-137466A. The content thereof is incorporated herein by reference.

In the present invention, an oxime compound having a fluorine atom can also be used as the photopolymerization initiator. Specific examples of the oxime compound having a fluorine atom include compounds described in JP2010-262028A, Compounds 24 and 36 to 40 described in JP2014-500852A, and Compound (C-3) described in JP2013-164471A. The contents thereof are incorporated herein by reference.

In the present invention, an oxime compound having a nitro group can be used as the photopolymerization initiator. It is preferable that the oxime compound having a nitro group is a dimer. Specific examples of the oxime compound having a nitro group include a compound described in paragraphs “0031” to “0047” of JP2013-114249A and paragraphs “0008” to “0012” and “0070” to “0079” of JP2014-137466A, a compound described in paragraphs “0007” to 0025” of JP4223071B, and ADEKA ARKLS NCI-831 (manufactured by ADEKA Corporation).

In the present invention, an oxime compound having a benzofuran skeleton can also be used as the photopolymerization initiator. Specific examples thereof include OE-01 to OE-75 described in WO2015/036910A.

Specific examples of the oxime compound which are preferably used in the present invention are shown below, but the present invention is not limited thereto.

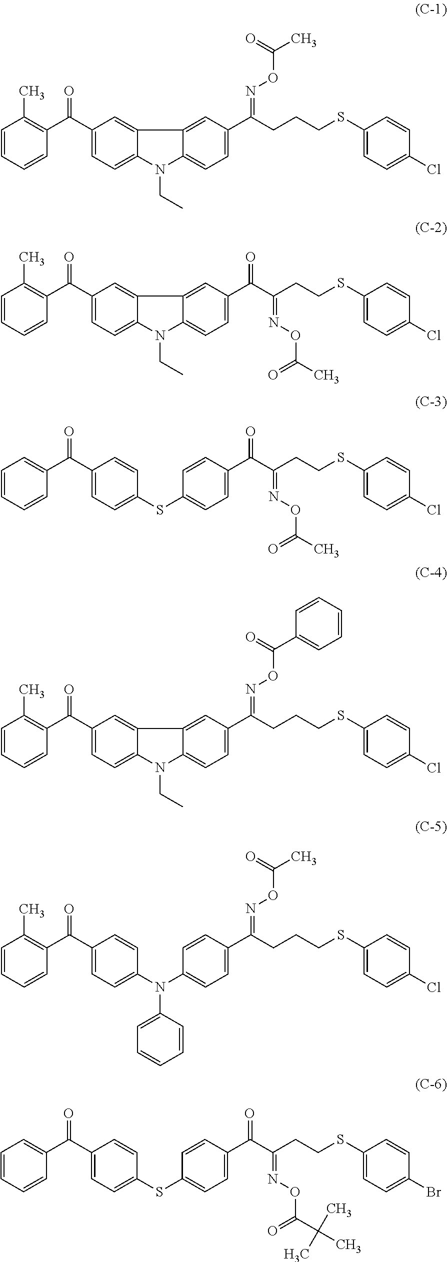 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

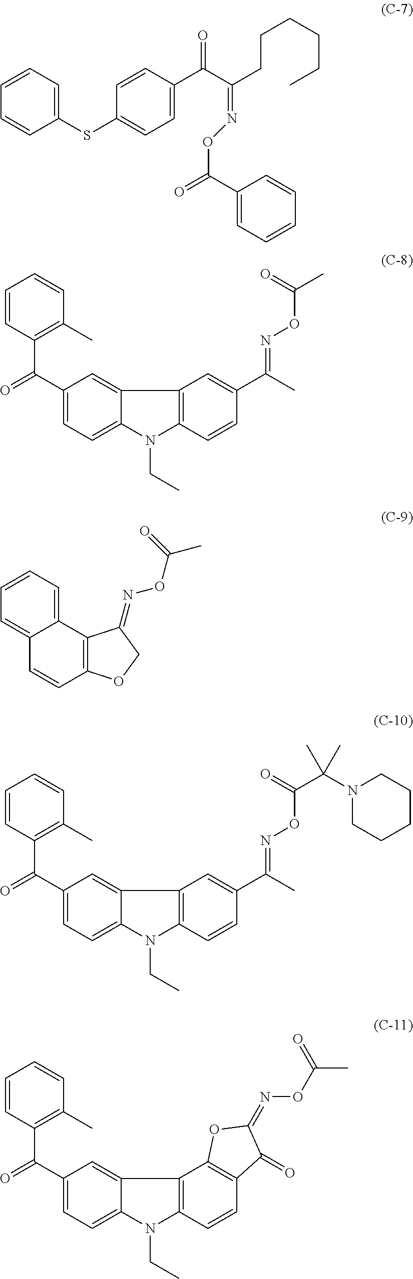

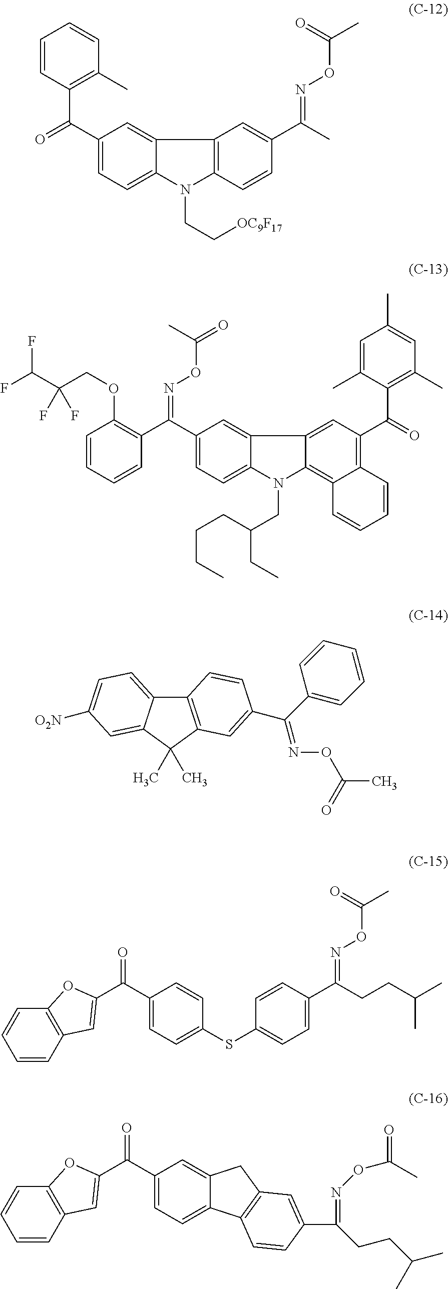

The oxime compound is preferably a compound having a maximum absorption wavelength in a wavelength range of 350 to 500 nm and more preferably a compound having a maximum absorption wavelength in a wavelength range of 360 to 480 nm. In addition, from the viewpoint of sensitivity, the molar absorption coefficient of the oxime compound at a wavelength of 365 nm or at a wavelength of 405 nm is preferably high, more preferably 1,000 to 300,000, still more preferably 2,000 to 300,000, and particularly preferably 5,000 to 200,000. The molar absorption coefficient of a compound can be measured using a well-known method. For example, it is preferable that the molar absorption coefficient can be measured using a spectrophotometer (Cary-5 spectrophotometer, manufactured by Varian Medical Systems, Inc.) and ethyl acetate as a solvent at a concentration of 0.01 g/L.

In the present invention, as the photopolymerization initiator, a bifunctional or tri- or more functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the coloring composition can be improved. Specific examples of the bifunctional or tri- or more functional photoradical polymerization initiator include dimers of the oxime compounds described in JP2010-527339A, JP2011-524436A, WO2015/004565A, paragraphs “0407” to “0412” of JP2016-532675A, and paragraphs “0039” to “0055” of WO2017/033680A; the compound (E) and compound (G) described in JP2013-522445A; Cmpd 1 to 7 described in WO2016/034963A; the oxime ester photoinitiators described in paragraph “0007” of JP2017-523465A; the photoinitiators described in paragraphs “0020” to “0033” of JP2017-167399A; and the photopolymerization initiator (A) described in paragraphs “0017” to “0026” of JP2017-151342A.

In a case where the coloring composition according to the embodiment of the present invention contains a photopolymerization initiator, the content of the photopolymerization initiator in the total solid content of the coloring composition according to the embodiment of the present invention is preferably 0.1 to 30 mass %. The lower limit is preferably 0.5 mass % or more and more preferably 1 mass % or more. The upper limit is preferably 20 mass % or less and more preferably 15 mass % or less. In the coloring composition according to the embodiment of the present invention, the photopolymerization initiator may be used singly or in combination of two or more kinds thereof. In a case where two or more kinds thereof are used, the total content thereof is preferably within the above-described range.

«Furyl Group-Containing Compound»

The coloring composition according to the embodiment of the present invention preferably contains a compound (hereinafter, also referred to as a furyl group-containing compound) including a furyl group. According to this aspect, a coloring composition having excellent curability at a low temperature can be obtained.

The structure of the furyl group-containing compound is not particularly limited as long as the compound includes a furyl group (group obtained by removing one hydrogen atom from furan).

As the furyl group-containing compound, compounds described in paragraphs “0049” to “0089” of JP2017-194662A can be used. In addition, compounds described in JP2000-233581A, JP1994-271558A, JP1994-293830A, JP1996-239421A, JP1998-508655A, JP2000-001529A, JP2003-183348A, JP2006-193628A, JP2007-186684A, JP2010-265377A, JP2011-170069A, and the like can also be used.

The furyl group-containing compound may be a monomer or a polymer. From the reason that it is easy to improve durability of the obtained film, a polymer is preferable. In a case of a polymer, the weight-average molecular weight thereof is preferably 2000 to 70000. The upper limit is preferably 60000 or less and more preferably 50000 or less. The lower limit is preferably 3000 or more, more preferably 4000 or more, and still more preferably 5000 or more. The polymer-type furyl group-containing compound is also a component corresponding to the resin in the coloring composition according to the embodiment of the present invention.

Examples of the monomer-type furyl group-containing compound (hereinafter, also referred to as a furyl group-containing monomer) include a compound represented by Formula (fur-1).

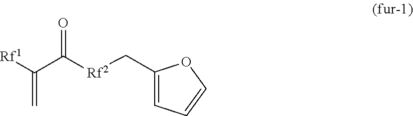

In the formula, Rf¹ represents a hydrogen atom or a methyl group, and Rf² represents a divalent linking group.

Examples of the divalent linking group represented by Rf² include an alkylene group, an arylene group, —O—, —CO—, —COO—, —OCO—, —NH—, —S—, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10. The alkylene group and the arylene group may have a substituent. Examples of the substituent include a hydroxy group.

The furyl group-containing monomer is preferably a compound represented by Formula (fur-1-1).

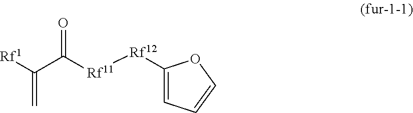

In the formula, Rf¹ represents a hydrogen atom or a methyl group, Rf¹¹ represents —O— or —NH—, and Rf¹² represents a single bond or a divalent linking group. Examples of the divalent linking group represented by Rf¹² include an alkylene group, an arylene group, —O—, —CO—, —COO—, —OCO—, —NH—, —S, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10. The alkylene group and the arylene group may have a substituent. Examples of the substituent include a hydroxy group.

Specific examples of the furyl group-containing monomer include compounds having the following structures. In the structural formulae, Rf¹ represents a hydrogen atom or a methyl group.

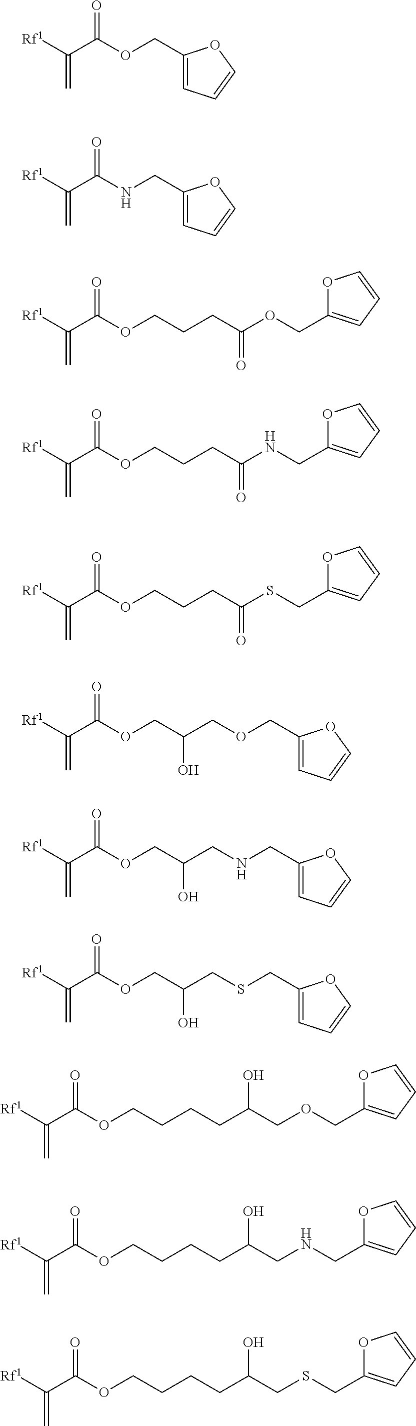

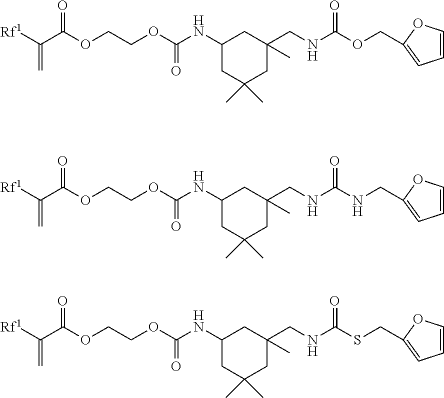

As the polymer-type furyl group-containing compound (hereinafter, also referred to as a furyl group-containing polymer), a resin including a repeating unit including a furyl group is preferable, and a resin including a repeating unit derived from the compound represented by Formula (fur-1) is more preferable. The concentration of the furyl group in the furyl group-containing polymer is preferably 0.5 to 6.0 mmol and still more preferably 1.0 to 4.0 mmol per 1 g of the furyl group-containing polymer. In a case where the concentration of the furyl group is 0.5 mmol or more, preferably 1.0 mmol or more, it is easy to form a pixel having excellent solvent resistance and the like. In a case where the concentration of the furyl group is 6.0 mmol or less, preferably 4.0 mmol or less, the temporal stability of the coloring composition is good.

The furyl group-containing polymer may include a repeating unit having an acid group and/or a repeating unit having a polymerizable group, in addition to the repeating unit having a furyl group. Examples of the acid group include a carboxyl group, a phosphoric acid group, a sulfo group, and a phenolic hydroxy group. Examples of the polymerizable group include ethylenically unsaturated groups such as a vinyl group, a (meth)allyl group, and a (meth)acryloyl group. In a case where the furyl group-containing polymer includes a repeating unit having an acid group, the acid value thereof is preferably 10 to 200 mgKOH/g and more preferably 40 to 130 mgKOH/g.

In a case where the furyl group-containing polymer includes a repeating unit having a polymerizable group, it is easy to form a pixel having better solvent resistance and the like.

The furyl group-containing polymer can be produced by a method described in paragraphs “0052” to “0101” of JP2017-194662A.

The content of the furyl group-containing compound in the total solid content of the coloring composition is preferably 0.1 to 70 mass %. The lower limit is preferably 2.5 mass % or more, more preferably 5.0 mass % or more, and still more preferably 7.5 mass % or more. The upper limit is preferably 65 mass % or less, more preferably 60 mass % or less, and still more preferably 50 mass % or less.

In addition, in a case where the furyl group-containing polymer is used as the furyl group-containing compound, the content of the furyl group-containing polymer in the resin included in the coloring composition is preferably 0.1 to 100 mass %. The lower limit is preferably 10 mass % or more and more preferably 15 mass % or more. The upper limit is preferably 90 mass % or less, more preferably 80 mass % or less, and still more preferably 70 mass % or less.

«Silane Coupling Agent»

The coloring composition according to the embodiment of the present invention can contain a silane coupling agent. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include the compounds described in paragraphs “0018” to “0036” of JP2009-288703A and the compounds described in paragraphs “0056” to “0066” of JP2009-242604A, the contents of which are incorporated herein by reference.

The content of the silane coupling agent in the total solid content of the coloring composition is preferably 0.1 to 5 mass %. The upper limit is preferably 3 mass % or less and more preferably 2 mass % or less. The lower limit is preferably 0.5 mass % or more and more preferably 1 mass % or more. The silane coupling agent may be used singly or in combination of two or more kinds thereof. In a case of using two or more kinds thereof, the total content thereof is preferably within the above-described range.

«Curing Accelerator»

For the purpose of promoting the reaction of polymerizable compounds or lowering a curing temperature, a curing accelerator may be added to the coloring composition according to the embodiment of the present invention. As the curing accelerator, a methylol-based compound (for example, the compounds exemplified as a crosslinking agent in paragraph “0246” of JP2015-034963A), amines, phosphonium salts, amidine salts, and amide compounds (each of which is the curing agent described in, for example, paragraph “0186” of JP2013-041165A), base generators (for example, the ionic compounds described in JP2014-055114A), cyanate compounds (for example, the compounds described in paragraph “0071” of JP2012-150180A), alkoxysilane compounds (for example, the alkoxysilane compounds having an epoxy group, described in JP2011-253054A), onium salt compounds (for example, the compounds exemplified as an acid generator in paragraph “0216” of JP2015-034963A, and the compounds described in JP2009-180949A), or the like can also be used. In a case where the coloring composition according to the embodiment of the present invention contains a curing accelerator, the content of the curing accelerator is preferably 0.3 to 8.9 mass % and more preferably 0.8 to 6.4 mass % with respect to the total solid content of the coloring composition.

«Polymerization Inhibitor»

The coloring composition according to the embodiment of the present invention can contain a polymerization inhibitor. Examples of the polymerization inhibitor include hydroquinone, p-methoxyphenol, di-tert-butyl-p-cresol, pyrogallol, t-butyl catechol, benzoquinone, 4,4′-thiobis(3-methyl-6-tert-butylphenol), 2,2′-methylenebis(4-methyl-6-t-butylphenol), and an N-nitrosophenylhydroxyamine salt (an ammonium salt, a cerous salt, or the like). Among these, p-methoxyphenol is preferable. The content of the polymerization inhibitor in the total solid content of the coloring composition is preferably 0.0001 to 5 mass %.

«Surfactant»

The coloring composition according to the embodiment of the present invention can contain a surfactant. As the surfactant, various surfactants such as a fluorine surfactant, a nonionic surfactant, a cationic surfactant, an anionic surfactant, or a silicon-based surfactant can be used. With regard to the surfactant, reference can be made to the description in paragraphs “0238” to “0245” of WO2015/166779A, the contents of which are incorporated herein by reference.

In the present invention, it is preferable that the surfactant is a fluorine surfactant. By containing a fluorine surfactant in the coloring composition, liquid characteristics (particularly, fluidity) are further improved, and liquid saving properties can be further improved. In addition, it is possible to form a film with a small thickness unevenness.

The fluorine content in the fluorine surfactant is preferably 3 to 40 mass %, more preferably 5 to 30 mass %, and particularly preferably 7 to 25 mass %. The fluorine surfactant in which the fluorine content is within the above-described range is effective in terms of the evenness of the thickness of the coating film or liquid saving properties and the solubility of the surfactant in the coloring composition is also good.

Examples of the fluorine surfactant include surfactants described in paragraphs “0060” to “0064” of JP2014-041318A (paragraphs “0060” to “0064” of the corresponding WO2014/017669A) and the like, and surfactants described in paragraphs “0117” to “0132” of JP2011-132503A, the contents of which are incorporated herein by reference. Examples of a commercially available product of the fluorine surfactant include: MEGAFACE F171, F172, F173, F176, F177, F141, F142, F143, F144, R30, F437, F475, F479, F482, F554, F780, EXP, MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine surfactant, a polymer of a fluorine atom-containing vinyl ether compound having a fluorinated alkyl group or a fluorinated alkylene ether group, and a hydrophilic vinyl ether compound can be preferably used. With regard to such a fluorine surfactant, reference can be made to the description in JP2016-216602A, the contents of which are incorporated herein by reference.

As the fluorine surfactant, a block polymer can also be used. Examples thereof include compounds described in JP2011-089090A. As the fluorine surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. For example, the following compound can also be used as the fluorine surfactant used in the present invention.

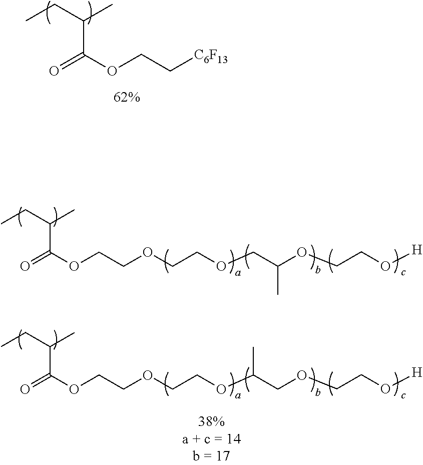

The weight-average molecular weight of the compound is preferably 3000 to 50000 and, for example, 14000. In the compound, “%” representing the proportion of a repeating unit is mol %.

In addition, as the fluorine surfactant, a fluorine-containing polymer including a repeating unit having an ethylenically unsaturated group in the side chain can be used. Specific examples thereof include compounds described in paragraphs “0050” to “0090” and paragraphs “0289” to “0295” of JP2010-164965A, and for example, MEGAFACE RS-101, RS-102, RS-718K, and RS-72-K manufactured by DIC Corporation. As the fluorine surfactant, compounds described in paragraphs “0015” to “0158” of JP2015-117327A can also be used.

The content of the surfactant in the total solid content of the coloring composition is preferably 0.001 mass % to 5.0 mass % and more preferably 0.005 to 3.0 mass %. The surfactant may be used singly or in combination of two or more kinds thereof. In a case of using two or more kinds thereof, the total content thereof is preferably within the above-described range.

«Ultraviolet Absorber»

The coloring composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, and the like can be used. With regard to details thereof, reference can be made to the description in paragraphs “0052” to “0072” of JP2012-208374A, paragraphs “0317” to “0334” of JP2013-068814A, and paragraphs “0061” to “0080” of JP2016-162946A, the contents of which are incorporated herein by reference. Examples of a commercially available product of the ultraviolet absorber include UV-503 (manufactured by Daito Chemical Co., Ltd.). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraphs “0049” to “0059” of JP6268967B can also be used. The content of the ultraviolet absorber in the total solid content of the coloring composition is preferably 0.01 to 10 mass % and more preferably 0.01 to 5 mass %. In the present invention, the ultraviolet absorber may be used singly or in combination of two or more kinds thereof. In a case where two or more kinds thereof are used, the total content thereof is preferably within the above-described range.

«Antioxidant»

The coloring composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitability used.

The content of the antioxidant in the total solid content of the coloring composition is preferably 0.01 to 20 mass % and more preferably 0.3 to 15 mass %. In the present invention, the antioxidant may be used singly or in combination of two or more kinds thereof. In a case where two or more kinds thereof are used, the total content thereof is preferably within the above-described range.

«Other Components»

Optionally, the coloring composition according to the embodiment of the present invention may further contain a sensitizer, a curing accelerator, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, and a chain transfer agent). By appropriately containing these components, properties such as film properties can be adjusted. The details of the components can be found in, for example, paragraphs “0183” and later of JP2012-003225A (corresponding to paragraph “0237” of US2013/0034812A) and paragraphs “0101” to “0104” and “0107” to “0109” of JP2008-250074A, the content of which is incorporated herein by reference. In addition, optionally, the coloring composition according to the embodiment of the present invention may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include compounds described in WO2014/021023A, WO2017/030005A, and JP2017-008219A. Examples of a commercially available product thereof include ADEKA ARKLS GPA-5001 (manufactured by ADEKA Corporation). In addition, the coloring composition according to the embodiment of the present invention may include a light-resistance improver.

The moisture content in the coloring composition according to the embodiment of the present invention is usually 3 mass % or less, preferably 0.01 to 1.5 mass % and more preferably in a range of 0.1 to 1.0 mass %. The moisture content can be measured by a Karl Fischer method.

The coloring composition according to the embodiment of the present invention can be used after viscosity is adjusted for the purposes of adjusting the state of a film surface (flatness or the like), adjusting a film thickness, or the like. The value of the viscosity can be appropriately selected as desired, and is, for example, preferably 0.3 mPa×s to 50 mPa×s, and more preferably 0.5 mPa×s to 20 mPa×s at 25° C. As for a method for measuring the viscosity, the viscosity can be measured, for example, with a temperature being adjusted to 25° C., using a viscometer RE85L (rotor: 1°34′×R24, measurement range of 0.6 to 1,200 mPa×s) manufactured by Toki Sangyo Co., Ltd.

The coloring composition according to the embodiment of the present invention can be preferably used as a coloring composition for forming a coloring pixel in a color filter. Examples of the coloring pixel include a red pixel, a green pixel, a blue pixel, a magenta pixel, a cyan pixel, and a yellow pixel. The coloring composition according to the embodiment of the present invention can be more preferably used as a coloring composition for forming a red pixel, a green pixel, or a blue pixel, and can be still more preferably used as a coloring composition for forming a red pixel or as a coloring composition for forming a green pixel.

In a case where the coloring composition according to the embodiment of the present invention is used as a color filter in applications for a liquid crystal display device, the voltage holding ratio of a liquid crystal display element comprising a color filter is preferably 70% or more, and more preferably 90% or more. A known method for obtaining a high voltage holding ratio can be appropriately incorporated, and examples of typical methods include use of high-purity materials (for example, reduction in ionic impurities) and control of the amount of acidic functional groups in a composition. The voltage holding ratio can be measured by, for example, the methods described in paragraph “0243” of JP2011-008004A and paragraphs “0123” to “0129” of JP2012-224847A.

A storage container of the coloring composition according to the embodiment of the present invention is not particularly limited, and a known storage container can be used. In addition, as the storage container, in order to suppress infiltration of impurities into the raw materials or the composition, a multilayer bottle in which a container inner wall having a six-layer structure is formed of six kinds of resins or a bottle in which a container inner wall having a seven-layer structure is formed of six kinds of resins is preferably used. Examples of such a container include a container described in JP2015-123351A.

<Method for Preparing Coloring Composition>

The coloring composition according to the embodiment of the present invention can be prepared by mixing the above-described components with each other. During the preparation of the coloring composition, all the components may be dissolved or dispersed in an organic solvent at the same time to prepare the coloring composition. Optionally, two or more solutions or dispersion liquids in which the respective components are appropriately blended may be prepared, and the solutions or dispersion liquids may be mixed with each other during use (during application) to prepare the coloring composition.

In addition, in the preparation of the coloring composition, a process of dispersing the pigment is preferably included. In the process of dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. In addition, it is preferable that rough particles are removed by filtering, centrifugal separation, and the like after pulverization treatment. In addition, as the process and the disperser for dispersing the pigment, the process and the disperser described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph “0022” of JP2015-157893A can be suitably used. In addition, in the process for dispersing the pigment, a refining treatment of particles in a salt milling step may be performed. A material, a device, process conditions, and the like used in the salt milling step can be found in, for example, JP2015-194521A and JP2012-046629A.

During the preparation of the coloring composition, it is preferable that the coloring composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultra-high molecular weight) such as polyethylene or polypropylene (PP). Among these materials, polypropylene (including high-density polypropylene) or nylon is preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be more reliably removed. With regard to the pore size value of the filter, reference can be made to a nominal value of filter manufacturers. As the filter, various filters provided by Nihon Pall Corporation (DFA4201NIEY and the like), Advantec Toyo Kaisha, Ltd., Nihon Entegris G. K. (formerly Nippon Microlith Co., Ltd.), Kitz Microfilter Corporation, and the like can be used.

In addition, it is preferable that a fibrous filter material is used as the filter. Examples of the fibrous filter material include polypropylene fiber, nylon fiber, and glass fiber. Examples of a commercially available product include SBP type series (SBP008 and the like), TPR type series (TPR002, TPR005, and the like), or SHPX type series (SHPX003 and the like), all of which are manufactured by Roki Techno Co., Ltd.

In a case where a filter is used, a combination of different filters (for example, a first filter and a second filter) may be used. In this case, the filtering using each of the filters may be performed once, or twice or more. In addition, a combination of filters having different pore sizes in the above-described range may be used. In addition, the filtering using the first filter may be performed only on the dispersion liquid, and the filtering using the second filter may be performed on a mixture of the dispersion liquid and other components.

<Film>

A film according to an embodiment of the present invention is a film obtained from the above-described coloring composition according to the embodiment of the present invention. The film according to the embodiment of the present invention can be preferably used as a coloring pixel of a color filter. Examples of the coloring pixel include a red pixel, a green pixel, a blue pixel, a magenta pixel, a cyan pixel, and a yellow pixel, and a red pixel, a green pixel, or a blue pixel is preferable and a red pixel or a green pixel is more preferable. The thickness of the film according to the embodiment of the present invention can be appropriately adjusted according to the purpose. For example, the thickness of the film is preferably 20 μm or less, more preferably 10 μm or less, and still more preferably 5 μm or less. The lower limit of the thickness of the film is preferably 0.1 μm or more, more preferably 0.2 μm or more, and still more preferably 0.3 μm or more.

<Color Filter>

Next, a color filter according to an embodiment of the present invention will be described. The color filter according to the embodiment of the present invention has the film according to the embodiment of the present invention. More preferably, the color filter according to the embodiment of the present invention has the film according to the embodiment of the present invention as a pixel of the color filter. The color filter according to the embodiment of the present invention can be used for a solid-state imaging element such as a charge coupled device (CCD) and a complementary metal-oxide semiconductor (CMOS), an image display device, or the like.

In the color filter according to the embodiment of the present invention, the thickness of the film according to the embodiment of the present invention can be appropriately adjusted depending on the purposes. The thickness of the film is preferably 20 μm or less, more preferably 10 μm or less, and still more preferably 5 μm or less. The lower limit of the thickness of the film is preferably 0.1 μm or more, more preferably 0.2 μm or more, and still more preferably 0.3 μm or more.

In the color filter according to the embodiment of the present invention, the width of the pixel (colored layer) is preferably 0.5 to 10.0 μm. The lower limit is preferably 0.7 μm or more and more preferably 0.8 μm or more. The upper limit is preferably 5.0 μm or less and more preferably 2.0 μm or less. In addition, the Young's modulus of the pixel (colored layer) is preferably 0.5 to 20 GPa and more preferably 2.5 to 15 GPa.

Each pixel (colored layer) included in the color filter according to the embodiment of the present invention preferably has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness of the pixel can be measured, for example, using an atomic force microscope (AFM) Dimension 3100 manufactured by Veeco Instruments, Inc. In addition, the contact angle of water on the pixel can be appropriately set to a preferred value and is typically in the range of 50° to 110°. The contact angle can be measured, for example, using a contact angle meter CV-DT-A Model (manufactured by Kyowa Interface Science Co., Ltd.). In addition, it is preferable that the volume resistivity value of the pixel is high. Specifically, the volume resistivity value of the pixel is preferably 10⁹ Ω×cm or more and more preferably 10¹¹ Ω×cm or more. The upper limit is not specified, but is, for example, preferably 10¹⁴ Ω×cm or less. The volume resistivity value of the pixel can be measured, for example, using an ultra-high resistance meter 5410 (manufactured by Advantest Corporation).

In addition, in the color filter according to the embodiment of the present invention, a protective layer may be provided on the surface of the film according to the embodiment of the present invention. By providing the protective layer, various functions such as oxygen shielding, low reflection, hydrophilicity/hydrophobicity, and shielding of light (ultraviolet rays, near-infrared rays, and the like) having a specific wavelength can be imparted. The thickness of the protective layer is preferably 0.01 to 10 μm and still more preferably 0.1 to 5 μm. Examples of a method for forming the protective layer include a method of forming the protective layer by applying a resin composition dissolved in an organic solvent, a chemical vapor deposition method, and a method of attaching a molded resin with an adhesive. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polycarbonate resin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an ink jet method can be used. As the organic solvent included in the resin composition, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, optionally, an additive such as organic or inorganic fine particles, an absorber of a specific wavelength (for example, ultraviolet rays, near-infrared rays, and the like), a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of a specific wavelength, a known absorber can be used. Examples of the ultraviolet absorber and near-infrared absorber include the above-described materials. The content of these additives can be appropriately adjusted, but is preferably 0.1 to 70 mass % and still more preferably 1 to 60 mass % with respect to the total weight of the protective layer.

In addition, as the protective layer, the protective layers described in paragraphs “0073” to “0092” of JP2017-151176A can also be used.

The color filter may have a structure in which pixels (colored layers) of each color are embedded in a region partitioned by a partition wall. In this case, it is preferable that the partition wall has a lower refractive index than each pixel. In addition, the partition wall may be formed with a configuration described in US2018/0040656A.

<Method for Manufacturing Color Filter>

Next, a method for manufacturing the color filter according to an embodiment of the present invention will be described. The color filter according to the embodiment of the present invention can be manufactured through a step of forming a coloring composition layer on a support using the above-described coloring composition according to the embodiment of the present invention, and a step of forming a pattern on the coloring composition layer by a photolithography method.

Pattern formation by a photolithography method preferably includes a step of forming a coloring composition layer on a support using the coloring composition according to the embodiment of the present invention, a step of patternwise exposing the coloring composition layer, and a step of removing an unexposed area of the coloring composition layer by development to form a pattern (pixel). Optionally, a step (pre-baking step) of baking the coloring composition layer and a step (post-baking step) of baking the developed pattern (pixel) may be provided.

In the step of forming a coloring composition according to the embodiment of the present invention, the coloring composition layer is formed on a support using the coloring composition according to the embodiment of the present invention. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, an undercoat layer may be provided on the silicon substrate so as to improve adhesiveness to an upper layer, prevent the diffusion of substances, or planarize the surface of the substrate.

As a method of applying the coloring composition, a known method can be used. Examples of the known method include: a drop casting method; a slit coating method; a spray method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and a metal mask printing; a transfer method using a mold or the like; and a nanoimprint lithography method. The application method using an ink jet method is not particularly limited, and examples thereof include a method (in particular, pp. 115 to 133) described in “Extension of Use of Ink Jet—Infinite Possibilities in Patent-” (published in February, 2005, S. B. Research Co., Ltd.) and methods described in JP2003-262716A, JP2003-185831A, JP2003-261827A, JP2012-126830A, and JP2006-169325A. In addition, with regard to the method for applying the coloring composition, reference can be made to the description in WO2017/030174A and WO2017/018419A, and the contents of which are incorporated herein by reference.

The coloring composition layer formed on the support may be dried (pre-baked). In a case of producing a film by a low-temperature process, pre-baking may not be performed. In a case where pre-baking is performed, the pre-baking temperature is preferably 150° C. or lower, more preferably 120° C. or lower, and still more preferably 110° C. or lower. The lower limit may be, for example, 50° C. or higher or 80° C. or higher. The pre-baking time is preferably 10 to 3000 seconds, more preferably 40 to 2500 seconds, and still more preferably 80 to 2200 seconds. Pre-baking can be performed using a hot plate, an oven, or the like.

Next, the coloring composition layer is patternwise exposed (exposing step). For example, the coloring composition layer can be patternwise exposed using a stepper exposure device or a scanner exposure device through a mask having a predetermined mask pattern. As a result, the exposed portion can be cured.

Examples of the radiation (light) which can be used during the exposure include g-rays and i-rays. In addition, light (preferably light having a wavelength of 180 to 300 nm) having a wavelength of 300 nm or less can also be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

The irradiation dose (exposure dose) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the unexposed area of the coloring composition layer is removed by development to form a pattern (pixel). The unexposed area of the coloring composition layer can be removed by development using a developer. Thus, the coloring composition layer of the unexposed area in the exposure step is eluted into the developer, and as a result, only a photocured portion remains. For example, the temperature of the developer is preferably 20° C. to 30° C. The development time is preferably 20 to 180 seconds. In addition, in order to further improve residues removing properties, a step of shaking the developer off per 60 seconds and supplying a new developer may be repeated multiple times.

Examples of the developer include an organic solvent and an alkaline developer. As the alkaline developer, an alkaline aqueous solution in which the alkaline agent is diluted with pure water is preferable. Examples of the alkaline agent include: an organic alkaline compound such as ammonia, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethyl bis(2-hydroxyethyl)ammonium hydroxide, choline, pyrrole, piperidine, and 1,8-diazabicyclo[5.4.0]-7-undecene; and an inorganic alkaline compound such as sodium hydroxide, potassium hydroxide, sodium carbonate, sodium bicarbonate, sodium silicate, and sodium metasilicate. In consideration of environmental aspects and safety aspects, the alkaline agent is preferably a compound having a high molecular weight. The concentration of the alkaline agent in the alkaline aqueous solution is preferably 0.001 to 10 mass % and more preferably 0.01 to 1 mass %. In addition, the developer may further contain a surfactant. Examples of the surfactant include the surfactants described above. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution factor is not particularly limited and, for example, can be set to be in a range of 1.5 to 100 times. In addition, it is also preferable to wash (rinse) with pure water after development. In addition, it is preferable that the rinsing is performed by supplying a rinsing liquid to the coloring composition layer after development while rotating the support on which the coloring composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to perform an additional exposure treatment or a heat treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be performed by the method described in KR10-2017-122130A.

<Structure Body>

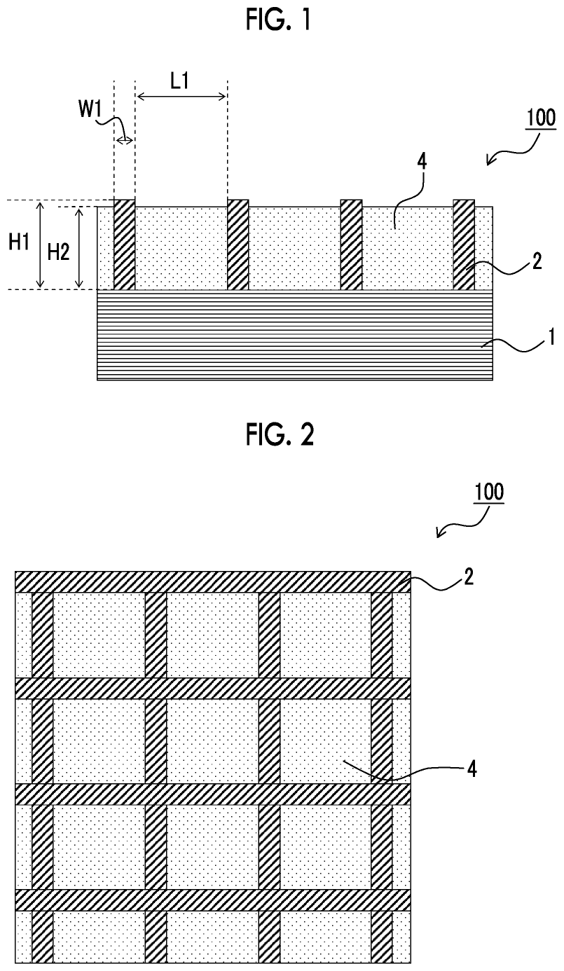

Next, a structure body according to an embodiment of the present invention will be described with reference to drawings. FIG. 1 is a side-sectional view showing an embodiment of the structure body according to the present invention, and FIG. 2 is a plan view of the structure body as viewed from directly above a support. As shown in FIGS. 1 and 2, a structure body 100 according to the embodiment of the present invention includes a support 1, a partition wall 2 provided on the support 1 and a colored layer 4 provided on a region of the support 1 partitioned by the partition wall 2. At least one kind (one color) of the colored layer 4 is obtained by using the above-described coloring composition according to the embodiment of the present invention.

In the structure body according to the embodiment of the present invention, the type of the support is not particularly limited. A substrate (silicon wafer, silicon carbide wafer, silicon nitride wafer, sapphire wafer, and glass wafer) used in various electronic devices such as a solid-state imaging element can be used. In addition, a substrate for a solid-state imaging element on which a photodiode is formed can also be used. In addition, as necessary, an undercoat layer may be provided on these substrates so as to improve adhesiveness to an upper layer, prevent the diffusion of substances, or planarize the surface.

As shown in FIGS. 1 and 2, the partition wall 2 is formed on the support 1. In this embodiment, as shown in FIG. 2, the partition walls 2 are formed in a lattice shape in a plan view seen from directly above the support 1. In this embodiment, the shape of the region partitioned by the partition wall 2 on the support 1 (hereinafter, also referred to as a shape of an opening portion of the partition wall) is a square shape, but the shape of the opening portion of the partition wall is not particularly limited, and may be, for example, a rectangular shape, a circular shape, an elliptical shape, a polygonal shape, or the like.

The material of the partition wall 2 is not particularly limited, but it is preferable that the partition wall 2 is formed of a material having a refractive index smaller than that of the colored layer 4. According to this aspect, a structure body in which the colored layer 4 having a large refractive index is surrounded by the partition wall 2 having a small refractive index can be formed. As a result, light which is to be leaked from the colored layer 4 having a large refractive index is easily reflected by the partition wall 2 and returned to the colored layer 4, and it is possible to suppress the leakage of light to the adjacent colored layer 4. As a specific example of the material of the partition wall 2, various inorganic materials and organic materials can be used. Examples of the organic material include acrylic resin, polystyrene resin, polyimide resin, and organic spin on glass (SOG) resin. Examples of the inorganic material include porous silica, polycrystalline silicon, silicon oxide, silicon nitride, and metal materials such as tungsten and aluminum.

A width W1 of the partition wall 2 is preferably 20 to 500 nm. The lower limit is preferably 30 nm or more, more preferably 40 nm or more, and still more preferably 50 nm or more. The upper limit is preferably 300 nm or less, more preferably 200 nm or less, and still more preferably 100 nm or less.

In addition, a height H1 of the partition wall 2 is preferably 200 nm or more, more preferably 300 nm or more, and still more preferably 400 nm or more. The upper limit is preferably the thickness of the colored layer 4×200% or less and more preferably the thickness of the colored layer 4×150% or less, and it is still more preferable that the upper limit is substantially the same as the thickness of the colored layer 4.

A height-to-width ratio (height/width) of the partition wall 2 is preferably 1 to 100, more preferably 5 to 50, and still more preferably 5 to 30.

The colored layer 4 is formed in the region (opening portion of the partition wall) of the support 1 partitioned by the partition wall 2. The type of the colored layer 4 is not particularly limited. Examples thereof include colored layers of red, blue, green, magenta, cyan, and the like. The color and arrangement of the colored layer can be arbitrarily selected. Pixels other than the colored layer may be further formed in the region partitioned by the partition wall 2. Examples of the pixel other than the colored layer include a transparent pixel and a pixel of an infrared transmitting filter.

A width L1 of the colored layer 4 can be appropriately selected depending on applications. For example, the width L1 of the colored layer 4 is preferably 500 to 2000 nm, more preferably 500 to 1500 nm, and still more preferably 500 to 1000 nm.

A height (thickness) H2 of the colored layer 4 can be appropriately selected depending on applications. For example, the height H2 of the colored layer 4 is preferably 300 to 1000 nm, more preferably 300 to 800 nm, and still more preferably 300 to 600 nm. In addition, the height H2 of the colored layer 4 is preferably 50% to 150% of the height H1 of the partition wall 2, more preferably 70% to 130% of the height H1 of the partition wall 2, and still more preferably 90% to 110% of the height H1 of the partition wall 2.

In the structure body according to the embodiment of the present invention, it is also preferable that a protective layer is provided on the surface of the partition wall. By providing the protective layer on the surface of the partition wall 2, adhesiveness between the partition wall 2 and the colored layer 4 can be improved. As a material of the protective layer, various inorganic materials and organic materials can be used. Examples of the organic material include acrylic resin, polystyrene resin, polyimide resin, and organic spin on glass (SOG) resin. In addition, the protective layer can also be formed using a composition including a compound having an ethylenically unsaturated group.

The structure body according to the embodiment of the present invention can be preferably used for a color filter, a solid-state imaging element, an image display device, and the like.

<Solid-State Imaging Element>

A solid-state imaging element according to an embodiment of the present invention has the film according to the embodiment of the present invention. The configuration of the solid-state imaging element according to the embodiment of the present invention is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving portion of the photodiodes on the photodiodes and the transfer electrodes; have a device protective film formed of silicon nitride or the like, which is formed to cover the entire surface of the light-shielding film and the light receiving portion of the photodiodes, on the light-shielding film; and have a color filter on the device protective film. Furthermore, the solid-state imaging element may also be configured, for example, such that it has a light collecting unit (for example, a microlens, which is the same hereinafter) on a device protective film under a color filter (a side closer to the substrate), or has a light collecting unit on a color filter. In addition, the color filter may have a structure in which each coloring pixel is embedded in a space partitioned in, for example, a lattice shape by a partition wall. In this case, it is preferable that the partition wall has a lower refractive index than each coloring pixel. Examples of an imaging device having such a structure include devices described in JP2012-227478A, JP2014-179577A, and WO2018/043654A. An imaging device including the solid-state imaging element according to the embodiment of the present invention can also be used as a vehicle camera, a monitoring camera, and the like, in addition to a digital camera or electronic equipment (mobile phones or the like) having an imaging function.

<Image Display Device>

An image display device according to an embodiment of the present invention has the film according to the embodiment of the present invention. Examples of the image display device include a liquid crystal display device or an organic electroluminescence display device. The definitions of image display devices or the details of the respective image display devices are described in, for example, “Electronic Display Device (written by Akio Sasaki, Kogyo Chosakai Publishing Co., Ltd., published in 1990)”, “Display Device (written by Sumiaki Ibuki, Sangyo Tosho Co., Ltd., published in 1989)”, and the like. In addition, the details of a liquid crystal display device can be found in, for example, “Next-Generation Liquid Crystal Display Techniques (edited by Tatsuo Uchida, Kogyo Chosakai Publishing Co., Ltd., published in 1994)”. The liquid crystal display device to which the present invention is applicable is not particularly limited. For example, the present invention is applicable to various liquid crystal display devices described in “Next-Generation Liquid Crystal Display Techniques”.

### EXAMPLES

Hereinafter, the present invention will be described in detail using Examples. Materials, used amounts, proportions, treatment details, treatment procedures, and the like shown in the following examples can be appropriately changed within a range not departing from the scope of the present invention. Accordingly, the scope of the present invention is not limited to the following specific examples.

<Measurement of Weight-Average Molecular Weight (Mw)>

The weight-average molecular weight (Mw) of a resin was measured by gel permeation chromatography (GPC) according to the following conditions.

Types of columns: columns formed by connection of TOSOH TSKgel Super HZM-H, TOSOH TSKgel Super HZ4000, and TOSOH TSKgel Super HZ2000

Developing solvent: tetrahydrofiran

Column temperature: 40° C.

Flow rate (amount of a sample to be injected): 1.0 μL (sample concentration: 0.1 mass %)

Device name: HLC-8220GPC manufactured by Tosoh Corporation

Detector: refractive index (RI) detector

Calibration curve base resin: polystyrene resin

<Method for Measuring Acid Value>

The acid value of the resin represents a mass of potassium hydroxide required to neutralize acidic components per 1 g of solid content of the resin. The acid value of the resin was measured as follows. That is, a measurement sample was dissolved in a mixed solvent of tetrahydrofiran/water=9/1 (mass ratio), and the obtained solution was subjected to neutralization titration with a 0.1 mol/L sodium hydroxide aqueous solution at 25° C. using a potentiometric titrator (trade name: AT-510, manufactured by KYOTO ELECTRONICS MANUFACTURING CO., LTD.). An inflection point of a titration pH curve was set as a titration end point, and the acid value was calculated from the following equation.

A=56.11×Vs×0.5×f/w

A: acid value (mgKOH/g)

Vs: amount (mL) of the 0.1 mol/L sodium hydroxide aqueous solution used for the titration

f: titer of the 0.1 mol/L sodium hydroxide aqueous solution

w: mass (g) of the measurement sample (expressed in terms of solid contents)

<Method for Measuring Average Primary Particle Diameter of Pigment and Pigment Derivative>

The average primary particle diameter of the pigment and the pigment derivative was measured by directly measuring the size of the primary particle of the measurement sample from an electron micrograph using a transmission electron microscope (TEM). Specifically, the minor axis diameter and the major axis diameter of the primary particle of each pigment were measured, and the average thereof was defined as the particle diameter of the primary pigment. Next, for each of the 100 pigment particles, the volume of each pigment particle was obtained by approximating it to a cube having the obtained particle diameter, and the volume average particle diameter was defined as the average primary particle diameter. The pigment derivative was also measured by the same method.

<Synthesis of Pigment>

(Synthesis of Brominated Diketopyrrolopyrrole Pigment (DPP1))

To a stainless steel reaction vessel equipped with a reflux tube, 200 parts by mass of tert-amyl alcohol dehydrated by a molecular sieve and 140 parts by mass of sodium-tert-amyl alkoxide were added under a nitrogen atmosphere, and heated to 100° C. while stirring, thereby preparing an alcoholate solution. On the other hand, to a glass flask, 88 parts by mass of diisopropyl succinate and 153.6 parts by mass of 4-bromobenzonitrile were added, and heated to 90° C. while stirring to dissolve them with each other, thereby preparing a solution of a mixture thereof. The heated solution of the mixture was slowly added dropwise to the above-described alcoholate solution heated to 100° C. at a constant rate over 2 hours while vigorously stirring. After the dropwise addition, heating and stirring were continued at 90° C. for 2 hours to obtain an alkali metal salt of diketopyrrolopyrrole compound. Furthermore, to a glass jacketed reaction vessel, 600 parts by mass of methanol, 600 parts by mass of water, and 304 parts by mass of acetic acid were added, and cooled to −10° C. While spinning the cooled mixture on a share disk with a diameter of 8 cm at 4000 rpm using a high-speed stirring disperser, the previously obtained alkali metal salt solution of diketopyrrolopyrrole compound cooled to 75° C. was added thereto little by little. At this time, while cooling so that the temperature of the mixture consisting of methanol, acetic acid, and water was always kept −5° C. or lower, and while adjusting the rate of addition of the alkali metal salt of diketopyrrolopyrrole compound at 75° C., the addition was performed in small portions over approximately 120 minutes. After the addition of the alkali metal salt, red crystals were precipitated and a red suspension was generated. Subsequently, the obtained red suspension was washed and filtered using an ultrafiltration device at 5° C. to obtain a red paste. The paste was redispersed in 3500 parts of methanol cooled to 0° C. to prepare a suspension having a methanol concentration of approximately 90%, and stirred at 5° C. for 3 hours to perform particle sizing and washing with crystal transition. Subsequently, after filtering using the ultrafiltration device, the obtained water paste of diketopyrrolopyrrole compound was dried at 80° C. for 24 hours, and pulverized to obtain 150.8 parts by mass of brominated diketopyrrolopyrrole pigment represented by Formula (DPP1).

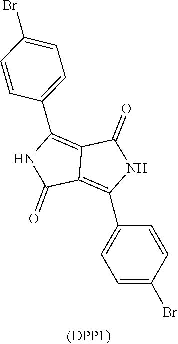 [SMILES: O=C1NC(c2ccc(Br)cc2)=C2C(=O)NC(c3ccc(Br)cc3)=C12 ; "(DPP1)"]

<Synthesis of Resin>

(Synthesis of Resin 1)

50 parts by mass of methyl methacrylate, 50 parts by mass of t-butyl methacrylate, and 45.4 parts by mass of propylene glycol monomethyl ether acetate (PGMEA) were charged into a reaction vessel, the inside of the reaction vessel was replaced with nitrogen gas. The inside of the reaction vessel was heated to 70° C., 6 parts by mass of 3-mercapto-1,2-propanediol was added thereto, 0.12 parts by mass of azobisisobutyronitrile (AIBN) was further added thereto, and the mixture was reacted for 12 hours. It was confirmed by solid content measurement that 95% thereof was reacted. Next, 9.7 parts by mass of pyromellitic acid anhydride, 70.3 parts by mass of PGMEA, and 0.20 parts by mass of 1,8-diazabicyclo-[5.4.0]-7-undecene (DBU) as a catalyst were added thereto, and the mixture was reacted at 120° C. for 7 hours. It was confirmed by acid value measurement that 98% or more of the acid anhydride was half-esterified, and the reaction was terminated. PGMEA was added thereto to adjust the concentration of solid contents to be 50 mass %, thereby obtaining a resin solution of resin 1 having an acid value of 43 mgKOH/g and a weight-average molecular weight (Mw) of 9000.

(Synthesis of Resin 2)

70.0 parts by mass of PGMEA was charged into a reaction vessel, the temperature was raised to 80° C., and the inside of the reaction vessel was replaced with nitrogen. hereafter, from a dropping tube, a mixture of 13.3 parts by mass of n-butyl methacrylate, 4.6 parts by mass of 2-hydroxyethyl methacrylate, 4.3 parts by mass of methacrylic acid, 7.4 parts by mass of ethylene oxide-modified acrylate of para-cumylphenol (ARONIX M110, manufactured by TOAGOSEI CO., LTD.), and 0.4 parts by mass of 2,2′-azobisisobutyronitrile was added dropwise thereto over 2 hours. After the dropwise addition, the reaction was continued for another 3 hours. After cooling to room temperature, PGMEA was added thereto to adjust the non-volatile content to be 20 mass %, thereby obtaining a resin solution of resin 2 having a weight-average molecular weight (Mw) of 26000.

(Synthesis of Resin 3)

90.0 parts by mass of PGMEA was charged into a reaction vessel and heated to 60° C. while injecting nitrogen gas into the vessel, and at the same temperature, a mixture of 57.2 parts by mass of furfuryl methacrylate, 30.6 parts by mass of 2-methacryloyloxyethyl succinic acid, 12.2 parts by mass of 2-hydroxyethyl methacrylate, and 5.0 parts by mass of 2,2′-azobis(2,4-dimethylvaleronitrile) was added dropwise thereto over 2 hours to perform a polymerization reaction. After the dropwise addition, the mixture was further reacted at 60° C. for 1 hour, 1.0 parts by mass of 2,2′-azobis(2,4-dimethylvaleronitrile) dissolved in 10.0 parts by mass of PGMEA was added thereto, and then stirring was continued at the same temperature for 3 hours to obtain a copolymer. Subsequently, dry air was injected into the reaction vessel, and 14.5 parts by mass of 2-methacryloyloxyethyl isocyanate, 14.5 parts by mass of PGMEA, 0.23 parts by mass of dibutyltin dilaurate, and 0.23 parts by mass of methquinone were added thereto, and the mixture was heated to 80° C. and stirred for 8 hours. After cooling to room temperature, PGMEA was added thereto to adjust the non-volatile content to be 20 mass %, thereby obtaining a resin solution of resin 3 having a weight-average molecular weight (Mw) of 28000.

<Preparation of Dispersion Liquid>

Raw materials described in the following tables were mixed, and then 230 parts by mass of zirconia beads having a diameter of 0.3 mm were added thereto to perform a dispersion treatment for 5 hours using a paint shaker. The beads were separated by filtration, and a dispersion liquid was produced. The numerical values described in the following tables indicate parts by mass. The value of the blending amount of the resin 1 is the value of the blending amount in the resin solution having a concentration of solid contents of 50 mass %. In addition, the blending amount of the resin 2 is the value of the blending amount in the resin solution having a concentration of solid contents of 20 mass %. In addition, as the average primary particle diameter of the pigment and the pigment derivative, an average primary particle diameter adjusted by the following method was used.

(Method for Adjusting Average Primary Particle Diameter of Pigment and Pigment Derivative)

100 parts by mass of the pigment or the pigment derivative, 1000 parts by mass of sodium chloride, and 120 parts by mass of diethylene glycol were charged into a 1-gallon stainless steel kneader (manufactured by INOUE MFG., INC.) and kneaded at 60° C. for 10 hours. Next, the kneaded mixture was put into warm water and stirred for 1 hour while heating to approximately 80° C. to form a slurry, the slurry was filtered and washed with water to remove salt and diethylene glycol, and then the resultant was dried at 80° C. for 24 hours and crushed, thereby adjusting the average primary particle diameter shown in the following tables. By changing the temperature condition, time, and amount of sodium chloride, the average primary particle diameter of the pigment and the pigment derivative was adjusted.

TABLE 1

| | | Dispersion liquid 1 | | Dispersion liquid 2 | | Dispersion liquid 3 | | Dispersion liquid 4 | |
|---|---|---|---|---|---|---|---|---|---|
| | | Red dispersion liquid | | Red dispersion liquid | | Red dispersion liquid | | Red dispersion liquid | |
| | | | Addition | | Addition | | Addition | | Addition |
| | | Material | amount | Material | amount | Material | amount | Material | amount |
| Pigment | Type | PR254 | 11.00 | PR254 | 11.00 | PR254 | 11.00 | PR254 | 11.00 |
| | Average primary | 40 | | 40 | | 40 | | 40 | |
| | particle diameter | | | | | | | | |
| | (nm) | | | | | | | | |
| Pigment | Type | Syn1 | 1.00 | Syn1 | 1.00 | Syn1 | 1.00 | Syn1 | 1.00 |
| derivative | Average primary | 50 | | 50 | | 30 | | 60 | |
| | particle diameter | | | | | | | | |
| | (nm) | | | | | | | | |

| | | | | | | | | |
|---|---|---|---|---|---|---|---|---|
| Resin | Resin 1 | 15.00 | Resin 1 | 15.00 | Resin 1 | 15.00 | Resin 1 | 15.00 |
| | Resin 2 | 5.00 | Resin 2 | 5.00 | Resin 2 | 5.00 | Resin 2 | 5.00 |
| Solvent D1 | PGME | 11.925 | PGME | 11.925 | PGME | 11.925 | PGME | 11.925 |
| Solvent D2 | PGMEA | 56.08 | PGMEA | 56.08 | PGMEA | 56.08 | PGMEA | 56.08 |

TABLE 2

| | | Dispersion liquid 5 | | Dispersion liquid 6 | | Dispersion liquid 7 | | Dispersion liquid 8 | |
|---|---|---|---|---|---|---|---|---|---|
| | | Red dispersion liquid | | Red dispersion liquid | | Red dispersion liquid | | Red dispersion liquid | |
| | | | Addition | | Addition | | Addition | | Addition |
| | | Material | amount | Material | amount | Material | amount | Material | amount |
| Pigment | Type | PR254 | 11.00 | PR177 | 11.00 | DPP1 | 11.00 | PR264 | 11.00 |
| | Average primary | 60 | | 40 | | 40 | | 40 | |
| | particle diameter | | | | | | | | |
| | (nm) | | | | | | | | |
| Pigment | Type | Syn1 | 1.00 | Syn2 | 1.00 | Syn1 | 1.00 | Syn1 | 1.00 |
| derivative | Average primary | 40 | | 40 | | 40 | | 40 | |
| | particle diameter | | | | | | | | |
| | (nm) | | | | | | | | |

| | | | | | | | | |
|---|---|---|---|---|---|---|---|---|
| Resin | Resin 1 | 15.00 | Resin 1 | 15.00 | Resin 1 | 15.00 | Resin 1 | 15.00 |
| | Resin 2 | 5.00 | Resin 2 | 5.00 | Resin 2 | 5.00 | Resin 2 | 5.00 |
| Solvent D1 | PGME | 11.925 | PGME | 11.925 | PGME | 11.925 | PGME | 11.925 |
| Solvent D2 | PGMEA | 56.08 | PGMEA | 56.08 | PGMEA | 56.08 | PGMEA | 56.08 |

TABLE 3

| | | Dispersion liquid 9 | | Dispersion liquid 10 | | Dispersion liquid 11 | | Dispersion liquid 12 | |
|---|---|---|---|---|---|---|---|---|---|
| | | Red dispersion liquid | | Yellow dispersion liquid | | Orange dispersion liquid | | Red dispersion liquid | |
| | | | Addition | | Addition | | Addition | | Addition |
| | | Material | amount | Material | amount | Material | amount | Material | amount |
| Pigment | Type | PR272 | 11.00 | PY139 | 11.00 | PO71 | 11.00 | PR254 | 11.00 |
| | Average primary | 40 | | 40 | | 40 | | 40 | |
| | particle diameter | | | | | | | | |
| | (nm) | | | | | | | | |
| Pigment | Type | Syn1 | 1.00 | Syn3 | 1.00 | Syn4 | 1.00 | Syn1 | 1.00 |
| derivative | Average primary | 40 | | 40 | | 40 | | 40 | |
| | particle diameter | | | | | | | | |
| | (nm) | | | | | | | | |

| | | | | | | | | |
|---|---|---|---|---|---|---|---|---|
| Resin | Resin 1 | 15.00 | Resin 1 | 15.00 | Resin 1 | 15.00 | Resin 1 | 15.00 |
| | Resin 2 | 5.00 | Resin 2 | 5.00 | Resin 2 | 5.00 | Resin 2 | 5.00 |
| Solvent D1 | PGME | 11.925 | PGME | 11.925 | PGME | 11.925 | ANONE | 11.925 |
| Solvent D2 | PGMEA | 56.08 | PGMEA | 56.08 | PGMEA | 56.08 | PGMEA | 56.08 |

TABLE 4

| | | Dispersion liquid 13 | | Dispersion liquid 14 | | Dispersion liquid 15 | | Dispersion liquid C1 | | Dispersion liquid C2 | |
|---|---|---|---|---|---|---|---|---|---|---|---|
| | | Red dispersion liquid | | Red dispersion liquid | | Red dispersion liquid | | Red dispersion liquid | | Red dispersion liquid | |
| | | | Addition | | Addition | | Addition | | Addition | | Addition |
| | | Material | amount | Material | amount | Material | amount | Material | amount | Material | amount |
| Pigment | Type | PR254 | 11.00 | PR254 | 11.00 | PR254 | 11.00 | PR254 | 11.00 | PR254 | 11.00 |
| | Average primary | 40 | | 40 | | 40 | | 40 | | 80 | |
| | particle diameter | | | | | | | | | | |
| | (nm) | | | | | | | | | | |
| Pigment | Type | Syn1 | 1.00 | Syn1 | 1.00 | Syn1 | 1.00 | Syn1 | 1.00 | Syn1 | 1.00 |
| derivative | Average primary | 40 | | 40 | | 40 | | 40 | | 80 | |
| | particle diameter | | | | | | | | | | |
| | (nm) | | | | | | | | | | |

| | | | | | | | | | | |
|---|---|---|---|---|---|---|---|---|---|---|
| Resin | Resin 1 | 15.00 | Resin 1 | 15.00 | Resin 1 | 15.00 | Resin 1 | 15.00 | Resin 1 | 15.00 |
| | Resin 2 | 5.00 | Resin 2 | 5.00 | Resin 2 | 5.00 | Resin 2 | 5.00 | Resin 2 | 5.00 |
| Solvent D1 | 2-Butanol | 11.925 | PGME | 7.95 | PGME | 23.85 | — | 0 | PGME | 11.925 |
| Solvent D2 | PGMEA | 56.08 | PGMEA | 60.05 | PGMEA | 44.15 | PGMEA | 68.00 | PGMEA | 56.08 |

The raw materials described in the above tables are as follows.

(Pigment)

PR177: C. I. Pigment Red 177

PR254: C. I. Pigment Red 254

PR264: C. I. Pigment Red 264

PR272: C. I. Pigment Red 272

DPP1: brominated diketopyrrolopyrrole pigment (DPP1); compound having the structure described above.

PY139: C. I. Pigment Yellow 139

P071: C. I. Pigment Orange 71

(Pigment Derivative)

Syn 1 to 4: compounds having the following structures

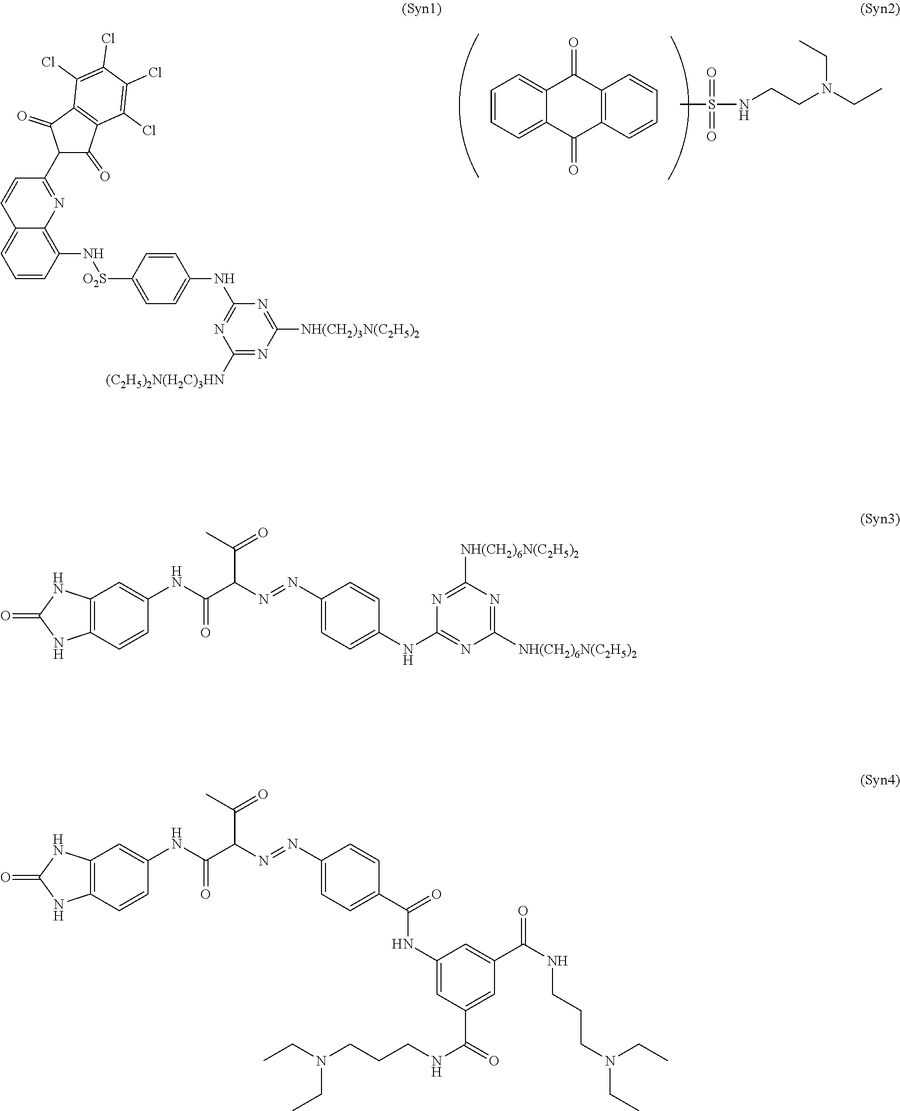

(Resin)

Resins 1 and 2: resins 1 and 2 described above

(Solvent)

PGMEA: propylene glycol monomethyl ether acetate (SP value=17.5 MPa^{0.5})

PGME: propylene glycol monomethyl ether (SP value=22.5 MPa^{0.5})

ANONE: cyclohexanone (SP value=19.6 MPa^{0.5})

2-Butanol: 2-butanol (SP value=22.2 MPa^{0.5})

<Preparation of Coloring Composition>

Raw materials described in the following table were mixed to prepare a coloring composition. Each value of the blending amounts of the resins 2 and 3 is the value of the blending amount in the resin solution having a solid content of 20 mass %.

TABLE 5

| | Dispersion | | | | Polymerizable | | Photopoly- | | | | | |
|---|---|---|---|---|---|---|---|---|---|---|---|---|
| | liquid | | Resin | | compound | | merization initiator | | Additive | | Solvent | |
| | | Part by | | Part by | | Part by | | Part by | | Part by | | Part by |
| | Type | mass | Type | mass | Type | mass | Type | mass | Type | mass | Type | mass |
| Example 1 | Dispersion | 46 | Resin 2 | 10 | Monomer 1 | 2.8 | Initiator 1 | 2 | Additive 1 | 0.4 | PGMEA | 38.8 |
| | liquid 1 | | | | | | | | | | | |
| Example 2 | Dispersion | 46 | Resin 2 | 10 | Monomer 1 | 2.8 | Initiator 1 | 2 | Additive 1 | 0.4 | PGMEA | 38.8 |
| | liquid 2 | | | | | | | | | | | |
| Example 3 | Dispersion | 46 | Resin 2 | 10 | Monomer 1 | 2.8 | Initiator 1 | 2 | Additive 1 | 0.4 | PGMEA | 38.8 |
| | liquid 3 | | | | | | | | | | | |
| Example 4 | Dispersion | 46 | Resin 2 | 10 | Monomer 1 | 2.8 | Initiator 1 | 2 | Additive 1 | 0.4 | PGMEA | 38.8 |
| | liquid 4 | | | | | | | | | | | |
| Example 5 | Dispersion | 46 | Resin 2 | 10 | Monomer 1 | 2.8 | Initiator 1 | 2 | Additive 1 | 0.4 | PGMEA | 38.8 |
| | liquid 5 | | | | | | | | | | | |
| Example 6 | Dispersion | 46 | Resin 2 | 10 | Monomer 1 | 2.8 | Initiator 1 | 2 | Additive 1 | 0.4 | PGMEA | 38.8 |
| | liquid 6 | | | | | | | | | | | |
| Example 7 | Dispersion | 46 | Resin 2 | 10 | Monomer 1 | 2.8 | Initiator 1 | 2 | Additive 1 | 0.4 | PGMEA | 38.8 |
| | liquid 7 | | | | | | | | | | | |
| Example 8 | Dispersion | 46 | Resin 2 | 10 | Monomer 1 | 2.8 | Initiator 1 | 2 | Additive 1 | 0.4 | PGMEA | 38.8 |
| | liquid 8 | | | | | | | | | | | |
| Example 9 | Dispersion | 46 | Resin 2 | 10 | Monomer 1 | 2.8 | Initiator 1 | 2 | Additive 1 | 0.4 | PGMEA | 38.8 |
| | liquid 9 | | | | | | | | | | | |
| Example 10 | Dispersion | 46 | Resin 2 | 10 | Monomer 1 | 2.8 | Initiator 1 | 2 | Additive 1 | 0.4 | PGMEA | 38.8 |
| | liquid 10 | | | | | | | | | | | |
| Example 11 | Dispersion | 46 | Resin 2 | 10 | Monomer 1 | 2.8 | Initiator 1 | 2 | Additive 1 | 0.4 | PGMEA | 38.8 |
| | liquid 11 | | | | | | | | | | | |
| Example 12 | Dispersion | 46 | Resin 2 | 10 | Monomer 1 | 2.8 | Initiator 1 | 2 | Additive 1 | 0.4 | PGMEA | 38.8 |
| | liquid 12 | | | | | | | | | | | |
| Example 13 | Dispersion | 46 | Resin 2 | 10 | Monomer 1 | 2.8 | Initiator 1 | 2 | Additive 1 | 0.4 | PGMEA | 38.8 |
| | liquid 13 | | | | | | | | | | | |
| Example 14 | Dispersion | 46 | Resin 2 | 10 | Monomer 1 | 2.8 | Initiator 1 | 2 | Additive 1 | 0.4 | PGMEA | 38.8 |
| | liquid 14 | | | | | | | | | | | |
| Example 15 | Dispersion | 46 | Resin 2 | 10 | Monomer 1 | 2.8 | Initiator 1 | 2 | Additive 1 | 0.4 | PGMEA | 38.8 |
| | liquid 15 | | | | | | | | | | | |
| Example 16 | Dispersion | 46 | Resin 3 | 10 | Monomer 1 | 2.8 | Initiator 1 | 2 | Additive 1 | 0.4 | PGMEA | 38.8 |
| | liquid 2 | | | | | | | | | | | |
| Example 17 | Dispersion | 46 | Resin 2 | 10 | Monomer 1 | 1.4 | Initiator 1 | 2 | Additive 1 | 0.4 | PGMEA | 38.8 |
| | liquid 2 | | | | Monomer 2 | 1.4 | | | | | | |
| Example 18 | Dispersion | 62 | Resin 2 | 2 | Monomer 1 | 2.2 | Initiator 1 | 1 | Additive 1 | 0.2 | PGMEA | 32.6 |
| | liquid 1 | | | | | | | | | | | |
| Example 19 | Dispersion | 80 | Resin 2 | 0.1 | Monomer 1 | 0.5 | Initiator 1 | 0.3 | Additive 1 | 0.1 | PGMEA | 19 |
| | liquid 1 | | | | | | | | | | | |
| Example 20 | Dispersion | 46 | Resin 2 | 10 | Monomer 1 | 2.8 | Initiator 2 | 2 | Additive 1 | 0.4 | PGMEA | 38.8 |
| | liquid 1 | | | | | | | | | | | |
| Example 21 | Dispersion | 46 | Resin 2 | 10 | Monomer 1 | 2.8 | Initiator 3 | 2 | Additive 1 | 0.4 | PGMEA | 38.8 |
| | liquid 1 | | | | | | | | | | | |
| Example 22 | Dispersion | 46 | Resin 2 | 10 | Monomer 1 | 2.8 | Initiator 4 | 2 | Additive 1 | 0.4 | PGMEA | 38.8 |
| | liquid 1 | | | | | | | | | | | |
| Example 23 | Dispersion | 46 | Resin 2 | 10 | Monomer 1 | 2.8 | Initiator 5 | 2 | Additive 1 | 0.4 | PGMEA | 38.8 |
| | liquid 1 | | | | | | | | | | | |
| Example 24 | Dispersion | 46 | Resin 2 | 10 | Monomer 1 | 2.8 | Initiator 1 | 2 | Additive 1 | 0.4 | Butyl acetate | 38.8 |
| | liquid 1 | | | | | | | | | | | |
| Example 25 | Dispersion | 46 | Resin 2 | 10 | Monomer 1 | 2.8 | Initiator 1 | 2 | Additive 1 | 0.4 | EEP | 38.8 |
| | liquid 1 | | | | | | | | | | | |
| Example 26 | Dispersion | 46 | Resin 2 | 10 | Monomer 3 | 2.8 | Initiator 1 | 2 | Additive 1 | 0.4 | PGMEA | 38.8 |
| | liquid 1 | | | | | | | | | | | |
| Example 27 | Dispersion | 46 | Resin 2 | 10 | Monomer 4 | 2.8 | Initiator 1 | 2 | Additive 1 | 0.4 | PGMEA | 38.8 |
| | liquid 1 | | | | | | | | | | | |
| Comparative | Dispersion | 46 | Resin 2 | 10 | Monomer 1 | 2.8 | Initiator 1 | 2 | Additive 1 | 0.4 | PGMEA | 39.6 |
| Example 1 | liquid C1 | | | | | | | | | | | |
| Comparative | Disspersion | 46 | Resin 2 | 10 | Monomer 1 | 2.8 | Initiator 1 | 2 | Additive 1 | 0.4 | PGMEA | 39.6 |
| Example 2 | liquid C2 | | | | | | | | | | | |

The abbreviations described in the above table are as follows.

(Dispersion Liquid)

Dispersion Liquids 1 to 15, C1, C2: dispersion liquids 1 to 15, C1, and C2 described above

(Resin)

Resins 2 and 3: resin solutions of resins 2 and 3 described above

(Polymerizable Compound)

Monomer 1: ARONIX M400 (manufactured by TOAGOSEI CO., LTD.)

Monomer 2: dipentaerythritol tetraacrylate

Monomer 3: ARONIX M350 (manufactured by TOAGOSEI CO., LTD.)

Monomer 4: DPHA (manufactured by Nippon Kayaku Co., Ltd.)

(Photopolymerization Initiator)

Initiator 1: IRGACURE 907 (manufactured by BASF)

Initiator 2: IRGACURE OXE 01 (manufactured by BASF)

Initiator 3: IRGACURE OXE 02 (manufactured by BASF)

Initiator 4: compound having the following structure

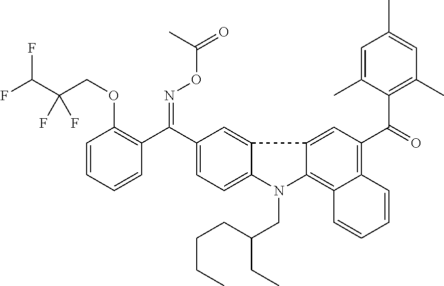

Initiator 5: compound having the following structure

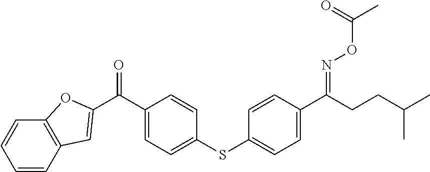 [SMILES: CC(=O)O/N=C(\CCC(C)C)c1ccc(Sc2ccc(C(=O)c3cc4ccccc4o3)cc2)cc1]

(Additive)

Additive 1: sensitizer (EAB-F, manufactured by Hodogaya Chemical Co., Ltd.)

(Solvent)

PGMEA: propylene glycol monomethyl ether acetate (SP value=17.5 MPa^{0.5})

Butyl acetate: butyl acetate (SP value=17.4 MPa^{0.5})

EEP: ethyl 3-propionate (SP value=17.8 MPA^{0.5})

<Evaluation of Color Unevenness>

Each coloring composition immediately after preparation was applied onto an undercoat layer of a silicon wafer with an undercoat layer using a spin coater (H-360S, manufactured by MIKASA CO., LTD.) so that the thickness of a film after pre-baking was 1.0 μm. Next, the coloring composition was pre-baked at 100° C. for 120 seconds to form a film. Foreign matter included in the film was detected by a foreign matter evaluation device ComPLUS III (manufactured by Applied Materials, Inc.), foreign matter (coarse particle) having a maximum width of 1.0 μm or more were visually classified from all the detected foreign matters, and then the number of classified foreign matters having a maximum width of 1.0 μm or more (number per 1 cm²) was counted. As the number of foreign matters is smaller, the color unevenness is smaller.

5: number of foreign matters was less than 10/wafer.

4: number foreign matters was 10/wafer or more and less than 30/wafer.

3: number foreign matters was 30/wafer or more and less than 100/wafer.

2: number foreign matters was 100/wafer or more and less than 300/wafer.

1: number of foreign matters was 300/wafer or more.

<Evaluation of Light Resistance>

Each coloring composition immediately after preparation was applied onto a soda glass (75 mm×75 mm square, 1.1 mm thickness) using a spin coater (H-360S, manufactured by MIKASA CO., LTD.). Next, the coloring composition was pre-baked at 100° C. for 2 minutes by using a hot plate to obtain a coating film. The obtained coating film was exposed to an exposure dose of 1,000 mJ/cm² by an ultra-high pressure mercury lamp (USH-500BY, manufactured by USHIO INC.). Subsequently, the coating film after exposure was heated at 200° C. for 5 minutes on a hot plate in an air atmosphere to obtain a film having a film thickness of 0.5 μm. Light transmittance (transmittance) of the obtained film in a range of 400 to 700 nm was measured by using MCPD-3000 manufactured by OTSUKA ELECTRONICS Co., LTD.

Next, a UV cut filter (manufactured by AS ONE Corporation, KU-1000100) was mounted on the produced film and a light resistance test was performed by using a weather meter (manufactured by Suga Test Instruments Co., Ltd., Xenon Weather Meter SX75) to irradiating light of 5,000,000 l×h over 50 hours. The temperature inside the tester was set to 63° C. The relative humidity in the tester was set to 50%. After performing the light resistance test, the transmittance of the film was measured, the maximum value of variation of transmittance was determined, and then the light resistance was evaluated based on the following standard.

In addition, the measurement of transmittance was performed 5 times for each sample, and the average value of the 3 times result except the maximum value and the minimum value was adopted. In addition, the maximum value of the variation of transmittance means a variation of transmittance of the film in a wavelength which has the largest variation of transmittance in a range of 400 to 700 nm before and after the light resistance test.

5: maximum value of variation of transmittance was 3% or less.

4: maximum value of variation of transmittance was more than 3% and 5% or less.

3: maximum value of variation of transmittance was more than 5% and 7% or less.

2: maximum value of variation of transmittance was more than 7% and 10% or less.

1: maximum value of variation of transmittance was more than 10%.

TABLE 6

| | Dispersion | Content of | Content of | | |
|---|---|---|---|---|---|
| | liquid | pigment | solvent D1 | Color | Light |
| | used | (mass %) | (mass %) | unevenness | resistance |
| Example 1 | Dispersion | 30.18 | 6.58 | 4 | 4 |
| | liquid 1 | | | | |
| Example 2 | Dispersion | 30.18 | 6.58 | 5 | 4 |
| | liquid 2 | | | | |
| Example 3 | Dispersion | 30.18 | 6.58 | 4 | 4 |
| | liquid 3 | | | | |
| Example 4 | Dispersion | 30.18 | 6.58 | 3 | 3 |
| | liquid 4 | | | | |
| Example 5 | Dispersion | 30.18 | 6.58 | 4 | 5 |
| | liquid 5 | | | | |
| Example 6 | Dispersion | 30.18 | 6.58 | 5 | 4 |
| | liquid 6 | | | | |
| Example 7 | Dispersion | 30.18 | 6.58 | 5 | 4 |
| | liquid 7 | | | | |
| Example 8 | Dispersion | 30.18 | 6.58 | 5 | 4 |
| | liquid 8 | | | | |
| Example 9 | Dispersion | 30.18 | 6.58 | 5 | 4 |
| | liquid 9 | | | | |
| Example 10 | Dispersion | 30.18 | 6.58 | 5 | 4 |
| | liquid 10 | | | | |
| Example 11 | Dispersion | 30.18 | 6.58 | 5 | 4 |
| | liquid 11 | | | | |
| Example 12 | Dispersion | 30.18 | 6.58 | 5 | 4 |
| | liquid 12 | | | | |
| Example 13 | Dispersion | 30.18 | 6.58 | 5 | 4 |
| | liquid 13 | | | | |
| Example 14 | Dispersion | 30.18 | 4.39 | 4 | 3 |
| | liquid 14 | | | | |
| Example 15 | Dispersion | 30.18 | 13.16 | 3 | 4 |
| | liquid 15 | | | | |
| Example 16 | Dispersion | 30.18 | 6.58 | 5 | 4 |
| | liquid 2 | | | | |
| Example 17 | Dispersion | 30.18 | 6.58 | 5 | 4 |
| | liquid 2 | | | | |
| Example 18 | Dispersion | 40.97 | 8.86 | 4 | 4 |
| | liquid 1 | | | | |
| Example 19 | Dispersion | 50.39 | 11.54 | 5 | 4 |
| | liquid 1 | | | | |
| Example 20 | Dispersion | 30.18 | 6.58 | 4 | 4 |
| | liquid 1 | | | | |
| Example 21 | Dispersion | 30.18 | 6.58 | 4 | 4 |
| | liquid 1 | | | | |
| Example 22 | Dispersion | 30.18 | 6.58 | 4 | 4 |
| | liquid 1 | | | | |
| Example 23 | Dispersion | 30.18 | 6.58 | 4 | 4 |
| | liquid 1 | | | | |
| Example 24 | Dispersion | 30.18 | 6.58 | 4 | 4 |
| | liquid 1 | | | | |
| Example 25 | Dispersion | 30.18 | 6.58 | 3 | 4 |
| | liquid 1 | | | | |
| Example 26 | Dispersion | 30.18 | 6.58 | 4 | 4 |
| | liquid 1 | | | | |
| Example 27 | Dispersion | 30.18 | 6.58 | 4 | 4 |
| | liquid 1 | | | | |
| Comparative | Dispersion | 30.18 | 0.00 | 2 | 1 |
| Example 1 | liquid C1 | | | | |
| Comparative | Dispersion | 30.18 | 6.58 | 1 | 1 |
| Example 2 | liquid C2 | | | | |

As is clear from the above-described results, the coloring composition of Examples was able to form a film having excellent color unevenness and light resistance.

The value of the content of pigment in the above table is the value of the content of pigment in the total solid content of the coloring composition. In addition, the value of the content of solvent D1 is the value of the content of a solvent having a solubility parameter of 18.0 to 26.0 MPa^{0.4} in the total amount of solvents included in the coloring composition.

### Example 101

A silicon wafer was coated with a Green composition using a spin coating method so that the thickness of a film after film formation was 1.0 μm. Next, the coating film was heated using a hot plate at 100° C. for 2 minutes. Next, using an i-ray stepper exposure device FPA-3000 i5+ (manufactured by Canon Corporation), exposure was performed with light having an exposure dose of 1,000 mJ/cm² through a mask having a dot pattern of 2 μm square. Next, puddle development was performed at 23° C. for 60 seconds using a tetramethylammonium hydroxide (TMAH) 0.3 mass % aqueous solution. Next, the coating film was rinsed by spin showering and was cleaned with pure water. Next, the Green composition was patterned by heating at 200° C. for 5 minutes using a hot plate. Likewise, a Red composition and a Blue composition were sequentially patterned to form red, green, and blue-colored patterns (Bayer pattern).

As the Red composition, the coloring composition of Example 1 was used.

The Green composition and the Blue composition will be described later.

The Bayer pattern refers to a pattern, as disclosed in the specification of U.S. Pat. No. 3,971,065A, in which a 2×2 array of color filter element having one Red element, two Green elements, and one Blue element is repeated.

The obtained color filter was incorporated into a solid-state imaging element according to a known method. The solid-state imaging element had a suitable image recognition ability.

(Green Composition)

The following components were mixed and stirred, and the obtained mixture was filtered through a nylon filter (manufactured by Nihon Pall Corporation) having a pore size of 0.45 μm to prepare a Green composition.

| | |
|---|---|
| Green pigment dispersion liquid | 73.7 parts by mass |
| Resin 101 | 0.3 parts by mass |
| Polymerizable Monomer 101 | 1.2 parts by mass |
| Photopolymerization Initiator (IRGACURE-OXE 01, | 0.6 parts by mass |
| manufactured by BASF) | |
| Surfactant 101 | 4.2 parts by mass |
| Ultraviolet absorber (UV-503, | 0.5 parts by mass |
| manufactured by Daito Chemical Co., Ltd.) | |
| PGMEA | 19.5 parts by mass |

(Blue Composition)

The following components were mixed and stirred, and the obtained mixture was filtered through a nylon filter (manufactured by Nihon Pall Corporation) having a pore size of 0.45 μm to prepare a Blue composition.

| | |
|---|---|
| Blue pigment dispersion liquid | 44.9 parts by mass |
| Resin 101 | 2.1 parts by mass |
| Polymerizable Monomer 101 | 1.5 parts by mass |
| Polymerizable Monomer 104 | 0.7 parts by mass |
| Photopolymerization Initiator (IRGACURE-OXE 01, | 0.8 parts by mass |
| manufactured by BASF) | |
| Surfactant 101 | 4.2 parts by mass |
| Ultraviolet absorber (UV-503, | 0.3 parts by mass |
| manufactured by Daito Chemical Co., Ltd.) | |
| PGMEA | 45.8 parts by mass |

The raw materials used for the preparation of the Green composition and the Blue composition are as follows.

Green Pigment Dispersion Liquid

6.4 parts by mass of C. I. Pigment Green 36, 5.3 parts by mass of C. I. Pigment Yellow 150, 5.2 parts by mass of a dispersant (Disperbyk-161, manufactured by BYK Chemie), 83.1 parts by mass of PGMEA were mixed with each other to obtain a mixed solution, and the mixed solution was mixed and dispersed using a beads mill (zirconia beads; diameter: 0.3 mm) for 3 hours. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2000 kg/cm³ at a flow rate of 500 g/min. This dispersion treatment was repeated 10 times. As a result, a Green pigment dispersion liquid was obtained.

Blue Pigment Dispersion Liquid

9.7 parts by mass of C. I. Pigment Blue 15:6, 2.4 parts by mass of C. I. Pigment Violet 23, 5.5 parts by mass of a dispersant (Disperbyk-161, manufactured by BYK Chemie), 82.4 parts by mass of PGMEA were mixed with each other to obtain a mixed solution, and the mixed solution was mixed and dispersed using a beads mill (zirconia beads; diameter: 0.3 mm) for 3 hours. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2000 kg/cm³ at a flow rate of 500 g/min. This dispersion treatment was repeated 10 times. As a result, a Blue pigment dispersion liquid was obtained.

Polymerizable monomer 101: KAYARAD DPHA (manufactured by Nippon Kayaku Co., Ltd.)

Polymerizable monomer 104: compound having the following structure

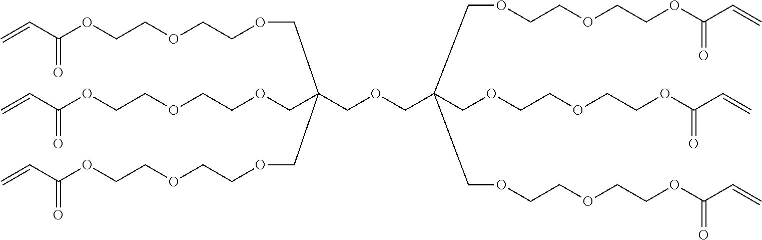 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

Resin 101: resin having the following structure (a numerical value added to a main chain represents a molar ratio; Mw=10,000, acid value=70 mgKOH/g)

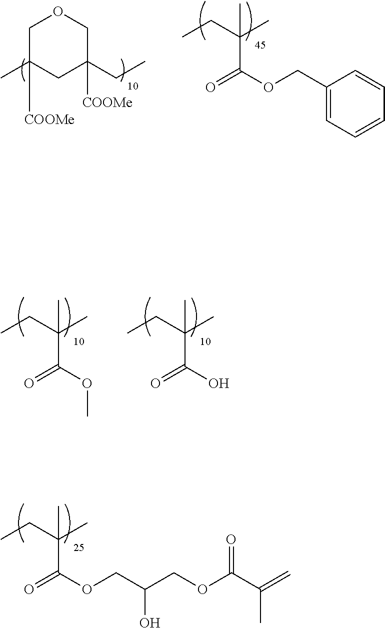

Surfactant 101: 1 mass % PGMEA solution of a compound having the following structure (Mw=14000; in the following formula, “%” representing the proportion of a repeating unit is mass %)

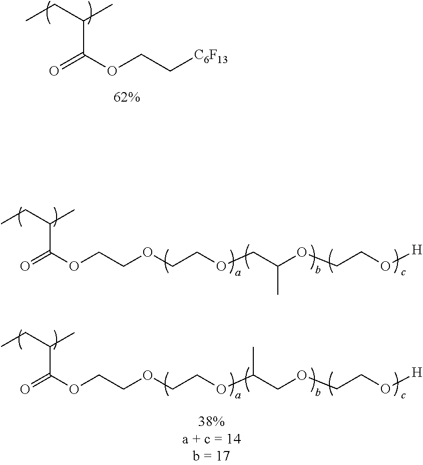

### EXPLANATION OF REFERENCES

1: support
2: partition wall
4: colored layer
100: structure body

What is claimed is:

1. A coloring composition comprising:
a pigment;
a pigment derivative;
a resin; and
a solvent,
wherein an average primary particle diameter of the pigment is 70 nm or less,
an average primary particle diameter of the pigment derivative is 70 nm or less, and
the solvent includes a solvent D1 having a solubility parameter of 18.0 to 26.0 MPa^{0.5}.

2. The coloring composition according to claim 1,
wherein the solvent D1 is included in an amount of 5 mass % or more in a total amount of the solvent.

3. The coloring composition according to claim 1,
wherein the solvent further includes a solvent D2 having a solubility parameter of less than 18 MPa^{0.5}.

4. The coloring composition according to claim 3,
wherein a content of the solvent D2 is 500 to 5000 parts by mass with respect to 100 parts by mass of the solvent D1.

5. The coloring composition according to claim 1,
wherein the pigment includes at least one selected from the group consisting of a diketopyrrolopyrrole compound and a phthalocyanine compound.

6. The coloring composition according to claim 1,
wherein the pigment is contained in an amount of 50 mass % or more in a total solid content of the coloring composition.

7. The coloring composition according to claim 1,
wherein the resin includes a resin having an aromatic carboxyl group.

8. The coloring composition according to claim 7,
wherein the resin having an aromatic carboxyl group is a resin including a repeating unit represented by Formula (b-1), 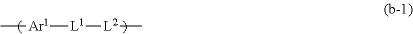
in the formula, Ar¹ represents a group including an aromatic carboxyl group, L¹ represents —COO— or —CONH—, and L² represents a divalent linking group.

9. The coloring composition according to claim 1,
wherein the resin contains a resin including a repeating unit derived from a compound represented by Formula (I), 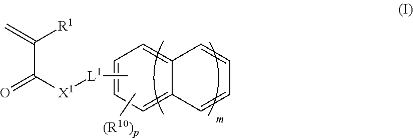
in the formula, X¹ represents O or NH,
R¹ represents a hydrogen atom or a methyl group,
L¹ represents a divalent linking group,
R¹⁰ represents a substituent,
m represents an integer of 0 to 2, and
p represents an integer of 0 or more.

10. The coloring composition according to claim 9,
wherein the resin including the repeating unit derived from the compound represented by Formula (I) further includes a repeating unit derived from an alkyl (meth)acrylate.

11. The coloring composition according to claim 1, further comprising:
a compound including a furyl group.

12. The coloring composition according to claim 1, further comprising:
a polymerizable monomer.

13. The coloring composition according to claim 1, further comprising:
a photopolymerization initiator.

14. A film obtained from the coloring composition according to claim 1.

15. A color filter comprising:
the film according to claim 14.

16. A method for manufacturing a color filter, comprising:
forming a coloring composition layer on a support using the coloring composition according to claim 1; and
forming a pattern on the coloring composition layer by a photolithography method.

17. A structure body comprising:
a support;
a partition wall provided on the support; and
a colored layer obtained from the coloring composition according to claim 1 and provided on a region of the support partitioned by the partition wall.

18. A solid-state imaging element comprising:
the film according to claim 14.

19. An image display device comprising:
the film according to claim 14.
